(19) United States
(12) Patent Application Publication
(10) Pub. No.: US 2004/0057485 A1
(43) Pub. Date: Mar. 25, 2004

(54) Semiconductor laser device, semiconductor laser module, and optical fiber amplifier

(75) Inventors: Yutaka Ohki, Tokyo (JP); Naoki Tsukiji, Tokyo (JP); Junji Yoshida, Tokyo (JP); Naoki Hayamizu, Tokyo (JP); Hiroshi Shimizu, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: The Furukawa Electric Co., Ltd., Tokyo (JP)

(21) Appl. No.: 10/619,437

(22) Filed: Jul. 16, 2003

(30) Foreign Application Priority Data
Jul. 16, 2002 (JP) 2002-207494
Jul. 16, 2002 (JP) 2002-207496

(51) Int. Cl. H01S 5/00

(52) U.S. Cl. 372/46

(57) ABSTRACT

An n-InP buffer layer, a GRIN-SCH-MQW active layer, and a p-InP spacer layer are sequentially grown on an n-InP substrate. A p-InP blocking layer and an n-InP blocking layer are grown adjacent to an upper region of the n-InP buffer layer, the GRIN-SCH-MQW active layer, and the p-InP spacer layer. A p-InP cladding layer, a p-GalnAsP contact layer, and a p-side electrode are grown on the p-InP spacer layer and the n-InP blocking layer. An n-side electrode is disposed on a rear surface of the n-InP substrate. A grating is disposed within the p-InP spacer layer. The grating selects a light of which number of longitudinal modes is equal to or more than 2 and equal to or less than 60, each of which has an intensity difference equal to or less than 10 decibels from a maximum intensity.

### BACKGROUND OF THE INVENTION

1) Field of the Invention

The present invention relates to a semiconductor laser device, a semiconductor laser module, and an optical fiber amplifier.

2) Description of the Related Art

Along with the recent development of optical communications including the Internet, an optical fiber amplifier is widely used in the middle of an optical transmission line in order to transmit a signal light over a long distance. Since intensity of a signal light is attenuated while propagating through the optical transmission line, it is necessary to maintain the intensity of the signal light within an appropriate range by recovering the intensity using the optical fiber amplifier.

There are two types of optical fiber amplifiers practically in use: an impurity-doping type amplifier such as an erbium-doped fiber amplifier (EDFA) of which the fiber core is doped with erbium ions, and a Raman-amplification type amplifier (hereinafter, “Raman amplifier”). Particularly, the Raman amplifier has an advantage that a wavelength of the signal light can be selected as desired. From this point of view, the Raman amplifier is regarded as a promising candidate for an optical amplifier in the near future.

A gain wavelength band of the impurity-doped optical fiber amplifier using a rare earth ion such as erbium is determined by energy level the ion doped. However, the gain wavelength band of the Raman amplifier is determined by the wavelength of a pimp light. Therefore, the Raman amplifier can amplify the signal light of a desired wavelength by selecting the pump light of an appropriate wavelength.

Generally, the Raman amplifier employs a semiconductor laser device as a pump source. Since the amplification gain of the Raman amplifier is proportional to output intensity of the semiconductor laser device, a high power semiconductor laser device is highly desirable as the pump source. However, when the intensity of the pump light per single wavelength is large, a stimulated Brillouin scattering becomes a serious problem. The larger the intensity of the pump light per single wavelength is, the more remarkable is the stimulated Brillouin scattering. Therefore, a multimode semiconductor laser device is used for the pump source, which outputs a laser light having a plurality of longitudinal modes.

However, when the multimode semiconductor laser device is used as the pump source, a relative intensity noise cannot be disregarded as compared with a case of using a single-mode semiconductor laser device.

Since the Raman amplification process is a fast physical phenomenon, a fluctuation in the intensity of the pump light induces a fluctuation of the Raman gain, resulting in a fluctuation of the intensity of an amplified signal. Consequently, if the relative intensity noise is large, it is not possible to obtain a stable Raman amplification. Particularly, it is well known that the relative intensity noise of the multimode laser increases after the laser light propagates over a certain distance, although the relative intensity noise immediately after the laser light is emitted is small. In the Raman amplifier, since it is necessary to transmit the pump light over a distance of about several tens of kilometers, if an increase of the relative intensity noise after the transmission is remarkable, the amplification gain becomes unstable.

Regarding a laser light having a single longitudinal mode, such as a laser light from a distributed feedback (DFB) laser, the relative intensity noise does not make a problem even after being transmitted over a distance. Therefore, in terms of suppressing the increase of the relative intensity noise, the single mode semiconductor laser device may offer a solution. However, when the single mode semiconductor laser device is used, the problem of the stimulated Brillouin scattering occurs as explained above. Consequently, it is not suitable to use the single mode semiconductor laser device such as the DFB semiconductor laser as the pump source, which means that a multimode semiconductor laser device that can suppress the increase of the relative intensity noise is highly needed.

### SUMMARY OF THE INVENTION

It is an object of the present invention to solve at least the problems in the conventional technology.

A semiconductor laser device according to one aspect of the present invention includes an emission facet with a first reflection coating; a reflection facet with a second reflection coating; an active layer that is formed between the first reflection coating and the second reflection coating; and an optical cavity that is formed by the emission facet and the reflection facet, and emits a light of which number of longitudinal modes is equal to or more than 2 and equal to or less than 60, wherein each longitudinal mode has an intensity difference equal to or less than 10 decibels from a maximum intensity.

A semiconductor laser device according to another aspect of the present invention includes an emission facet with a first reflection coating; a reflection facet with a second reflection coating; an active layer that is formed between the first reflection coating and the second reflection coating; and a grating that is disposed adjacent to the active layer and that selects a light of which number of longitudinal modes is equal to or more than 2 and equal to or less than 60, wherein each longitudinal mode has an intensity difference equal to or less than 10 decibels from a maximum intensity.

A semiconductor laser module according to still another aspect of the present invention includes a semiconductor laser device that has an emission facet with a first reflection coating; a reflection facet with a second reflection coating; an active layer that is formed between the first reflection coating and the second reflection coating; and a grating that is disposed adjacent to the active layer and that selects a light of which number of longitudinal modes is equal to or more than 2 and equal to or less than 60, wherein each longitudinal mode has an intensity difference equal to or less than 10 decibels from a maximum intensity. Moreover, the semiconductor laser module includes an optical fiber that guides a laser light output from the semiconductor laser device to the outside; and an optical coupling lens system that optically couples the semiconductor laser device and the optical fiber.

An optical fiber amplifier according to still another aspect of the present invention includes a pump source with a semiconductor laser module including a semiconductor laser device, an optical fiber that guides a laser light output from the semiconductor laser device to the outside, and an optical coupling lens system that optically couples the semiconductor laser device and the optical fiber; an optical transmission line to transmit a signal light; an optical fiber for amplification that is connected to the optical transmission line and amplifies the signal light based on a Raman amplification; a coupler that inputs a pump light from the pump source into the optical fiber; and an optical transmission line for the pump light that connects the pump source and the coupler. The semiconductor laser device includes an emission facet with a first reflection coating; a reflection facet with a second reflection coating; an active layer that is formed between the first reflection coating and the second reflection coating; and a grating that is disposed adjacent to the active layer and that selects a light of which number of longitudinal modes is equal to or more than 2 and equal to or less than 60, wherein each longitudinal mode has an intensity difference equal to or less than 10 decibels from a maximum intensity.

A semiconductor laser device according to still another aspect of the present invention includes an emission facet with a first reflection coating; a reflection facet with a second reflection coating; an active layer formed between the first reflection coating and the second reflection coating, and outputs a laser light having a plurality of longitudinal modes; and a modulation unit that generates a modulation signal for modulating a bias current injected into the active layer and, superimposes the modulation signal on the bias current, wherein the modulation unit gives a return loss of a stimulated Brillouin scattering equal to or less than a value obtained by adding a predetermined value to a Rayleigh scattering level based on the modulation of the laser light.

A semiconductor laser device according to still another aspect of the present invention includes an emission facet with a first reflection coating; a reflection facet with a second reflection coating; an active layer formed between the first reflection coating and the second reflection coating, and outputs a laser light having a plurality of longitudinal modes; and a grating that selects a plurality of high power longitudinal modes, wherein each longitudinal mode has an intensity difference equal to or less than 10 decibels from a maximum intensity, wherein the grating gives a return loss of a stimulated Brillouin scattering equal to or less than a value obtained by adding a predetermined value to a Rayleigh scattering level based on the selected number of the high power longitudinal modes.

A semiconductor laser module according to still another aspect of the present invention includes a semiconductor laser device that has an emission facet with a first reflection coating; a reflection facet with a second reflection coating; and an active layer formed between the first reflection coating and the second-reflection coating, and outputs a laser light having a plurality of longitudinal modes. The semiconductor laser module further includes an optical fiber that guides a laser light output from the semiconductor laser device to the outside; and an optical coupling lens system that optically couples the semiconductor laser device and the optical fiber in such a manner that the optical coupling efficiency between the semiconductor laser device and the optical fiber is deviated from a maximum value. The semiconductor laser module gives a return loss of a stimulated Brillouin scattering equal to or less than a value obtained by adding a predetermined value to a Rayleigh scattering level based on an attenuation of the optical coupling efficiency.

A semiconductor laser module according to still another aspect of the present invention includes a semiconductor laser device that has an emission facet with a first reflection coating; a reflection facet with a second reflection coating; and an active layer formed between the first reflection coating and the second reflection coating, and outputs a laser light having a plurality of longitudinal modes. The semiconductor laser module further includes an optical fiber that guides a laser light output from the semiconductor laser device to the outside; and an optical attenuator that attenuates the laser light. The semiconductor laser module gives a return loss of a stimulated Brillouin scattering equal to or less than a value obtained by adding a predetermined value to a Rayleigh scattering level based on the attenuation by the optical attenuator.

A Raman amplifier according to still another aspect of the present invention uses, as a pump source for a wideband Raman amplification, either of the semiconductor laser device and the semiconductor laser module according to the present invention.

The other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 is a cross-section of a semiconductor laser device according to a first embodiment of the present invention;

FIG. 2 is a schematic diagram of the semiconductor laser device according to the first embodiment;

FIG. 3 is an oscillation spectrum of the semiconductor laser device according to the first embodiment;

FIG. 4 is an example of a grating structure according to the first embodiment;

FIG. 5 is another oscillation spectrum of the semiconductor laser device according to the first embodiment;

FIGS. 6A, 6B, and 6C are other examples of the grating structure according to the first embodiment;

FIG. 7 is relative intensity noise characteristics of a laser light having 63 longitudinal modes, each of which has an intensity difference equal to or less than 10 decibels from a maximum intensity;

FIG. 8 is relative intensity noise characteristics of a laser light in a single mode;

FIG. 9 is relative intensity noise characteristics of a laser light having 18 longitudinal modes, each of which has a intensity difference equal to or less than 10 decibels from a maximum intensity;

FIG. 10 is an oscillation spectrum of a laser light that is used to measure the relative intensity noise shown in FIG. 7;

FIG. 11 is an oscillation spectrum of a laser light that is used to measure the relative intensity noise shown in FIG. 8;

FIG. 12 is an oscillation spectrum of a laser light that is used to measure the relative intensity noise shown in FIG. 9;

FIG. 13 is a graph that explains no mode partition noise occurs immediately after a laser light is emitted;

FIG. 14 is a graph that explains a mode partition noise occurs after transmission of the laser light over a distance;

FIG. 15 is a side cross-sectional view of a semiconductor laser module according to a second embodiment of the present invention;

FIG. 16 is a schematic diagram of an optical fiber amplifier according to the third embodiment of the present invention;

FIG. 17 is a schematic diagram of an application example of an optical fiber amplifier according to a third embodiment of the present invention;

FIG. 18 is a schematic diagram of an optical fiber amplifier employing a co-propagating pumping system, as a modification of the optical fiber amplifier according to the third embodiment;

FIG. 19 is a schematic diagram of an application example of the optical fiber amplifier shown in FIG. 18;

FIG. 20 is a schematic diagram of an optical fiber amplifier employing a bidirectional pumping system, as a modification of the optical fiber amplifier according to the third embodiment;

FIG. 21 is a schematic diagram of an application example of the optical fiber amplifier shown in FIG. 20;

FIG. 22 is a schematic diagram of a wavelength division multiplexing (WDM) communication system using the optical fiber amplifier according to the third embodiment;

FIG. 23 is a cross-section of the semiconductor laser device according to a fourth embodiment of the present invention;

FIG. 24 is a schematic diagram of the semiconductor laser device according to the fourth embodiment;

FIG. 25 is a cross-section of the semiconductor laser device shown in FIG. 24 cut along a line A-A;

FIG. 26 illustrates a relation between an oscillation spectrum and longitudinal modes of the semiconductor laser device shown in FIG. 23;

FIG. 27 illustrates a time variation of an optical output when a modulation frequency signal is superimposed on a bias current;

FIG. 28 illustrates a variation of an optical output when the modulation signal-superimposed current is applied, based on light-current characteristics;

FIG. 29 illustrates a time variation of a drive current when the modulation frequency signal is superimposed on the bias current;

FIGS. 30A and 30B illustrate a relative increase of a threshold of a stimulated Brillouin scattering when the modulation signal-superimposed current is applied and when a grating is partially provided based on a cavity length;

FIG. 31 illustrates a change of a longitudinal mode spectrum width with a change of the modulation amplitude;

FIG. 32 illustrates a change of the threshold of the stimulated Brillouin scattering with a change of the longitudinal mode spectrum width;

FIG. 33 is a schematic diagram of a measurement setup to detect the stimulated Brillouin scattering and measure the relative intensity noise;

FIG. 34 illustrates a relation between a modulation factor and a return loss;

FIG. 35 illustrates a change of relative intensity noise characteristics when changing a modulation factor or a return loss;

FIG. 36 illustrates a relation between the relative intensity noise and the return loss;

FIG. 37 is an oscillation spectrum of a semiconductor laser device having 14 longitudinal modes, each of which has a intensity difference equal to or less than 10 decibels from a maximum intensity;

FIG. 38 is an oscillation spectrum of a semiconductor laser device having 20 longitudinal modes, each of which has a intensity difference equal to or less than 10 decibels from a maximum intensity;

FIG. 39 is an oscillation spectrum of a semiconductor laser device having 6 longitudinal modes, each of which has a intensity difference equal to or less than 10 decibels from a maximum intensity;

FIG. 40 illustrates a relation between the return loss and number of longitudinal modes, each of which has a intensity difference equal to or less than 10 decibels from a maximum intensity, when changing a temperature of the semiconductor laser device;

FIG. 41 illustrates a relation between a return loss and an attenuation factor based on a defocusing; and

FIG. 42 is a schematic diagram of a semiconductor laser module according to the fourth embodiment.

### DETAILED DESCRIPTION

Exemplary embodiments of a display device of the present invention are explained below with reference to the drawings. In the description of drawings, identical or similar portions are assigned with an identical or similar reference numeral, and those portions are regarded to have the same function unless specified otherwise. The drawings are schematic diagrams, and it is necessary to pay attention that the drawing do not necessarily reflect exact relations between a thickness and a width of layers, and ratios thereof.

A semiconductor laser device according to a first embodiment of the present invention outputs a plurality of longitudinal modes. The semiconductor laser device decreases a relative intensity noise by limiting number of the longitudinal modes within 60, each of which has an intensity difference equal to or less than 10 decibels from a maximum intensity.

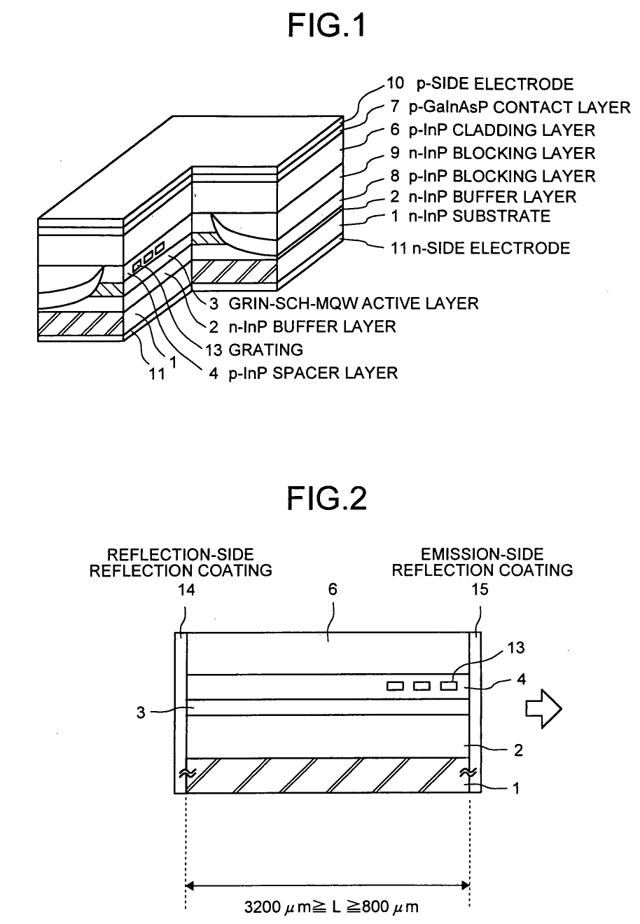

FIG. 1 and FIG. 2 are a cross-section of a semiconductor laser device and a side cross-sectional view of the semiconductor laser device according to the first embodiment, respectively.

An n-InP buffer layer 2, a graded index separate confinement heterostructure multiple quantum well (GRIN-SCH-MQW) active layer 3, and a p-InP spacer layer 4 are sequentially grown on an n-InP substrate 1. An upper region of the n-InP buffer layer 2, the GRIN-SCH-MQW active layer 3, and the p-InP spacer layer 4 are in a mesa stripe structure having a longitudinal direction in a light emission direction. A p-InP blocking layer 8 and an n-InP blocking layer 9 are sequentially grown adjacent to this structure. A p-InP cladding layer 6 and a p-GalnAsP contact layer 7 are grown on the p-InP spacer layer 4 and the n-InP blocking layer 9. A p-side electrode 10 is disposed on the p-GalnAsP contact layer 7. An n-side electrode 11 is disposed on a rear surface of the n-InP substrate 1. An emission-side reflection coating 15 is disposed on a laser light emission facet. A reflection-side reflection coating 14 is disposed on a reflection facet that is opposite to the laser light emission facet. A grating 13 is disposed within the p-InP spacer layer 4.

The n-InP buffer layer 2 has both functions of a cladding layer and a buffer layer. Specifically, the n-InP buffer layer 2 has a function of confining a light generated from the GRIN-SCH-MQW active layer 3 in a vertical direction, having a lower refractive index than an effective refractive index of the GRIN-SCH-MQW active layer 3.

The GRIN-SCH-MQW active layer 3 has a function of effectively confining carriers injected from the p-side electrode 10 and the n-side electrode 11. The GRIN-SCH-MQW active layer 3 has a plurality of quantum well layers, and exhibits a quantum confinement effect in each quantum well layer. Based on this quantum confinement effect, the semiconductor laser device according to the first embodiment has high light-emission efficiency.

The p-GalnAsP contact layer 7 is to make an ohmic junction between the p-InP cladding layer 6 and the p-side electrode 10. The p-GalnAsP contact layer 7A is doped with a large amount of a p-type impurity, thereby to realize an ohmic contact between the p-InP cladding layer 6 and the p-side electrode 10.

The p-InP blocking layer 8 and the n-InP blocking layer 9 are to confine an injected current. In the semiconductor laser device according to the first embodiment, the p-side electrode 10 functions as an anode. Therefore, when a voltage is applied, an inverse bias is applied between the n-InP blocking layer 9 and the p-InP blocking layer 8. Consequently, no current flows from the n-InP blocking layer 9 to the p-InP blocking layer 8. The current injected from the p-side electrode 10 is well confined, and flows into the GRIN-SCH-MQW active layer 3 in a high density. When the current flows into the GRIN-SCH-MQW active layer 3 in the high density, the carrier density in the active layer 3 increases, and as a result, the light emission efficiency is improved.

The reflection-side reflection coating 14 has a reflectivity of 80 percent or higher, preferably 98 percent or higher. On the other hand, the light emission-side reflection coating 15 prevents a reflection of a laser light on the light emission facet. Therefore, the light emission-side reflection coating 15 employs a film structure having a low reflectivity, that is, not higher than five percent, preferably about one percent. Since the reflectivity of the light emission-side reflection coating 15 is optimized according to a cavity length, the reflectivity may take other values.

The grating 13 is made of p-GalnAsP. As the grating 13 is made of a semiconductor material different from the surrounding p-InP spacer layer 4, the grating 13 reflects a component having a predetermined wavelength out of the light generated from the GRIN-SCH-MQW active layer 3. Based on the presence of the grating 13, the semiconductor laser device according to the first embodiment has a plurality of longitudinal modes in the emitted laser light. The semiconductor laser device according to the first embodiment has an adjusted structure of the grating 13 such that the number of the longitudinal modes does not exceed 60, each of which has an intensity difference equal to or less than 10 decibels from a maximum intensity.

The grating 13 has a thickness of 20 nanometers, and has a length Lg of 50 micrometers from the facet of the emission-side reflection coating 15 toward the reflection-side reflection coating 14. A plurality of the gratings 13 is formed periodically with a pitch of about 220 nanometers. Each grating 13 selects a wavelength of a laser light having a center wavelength of 1.48 micrometers. The grating 13 provides a satisfactory linearity of drive current-optical output characteristics, and improves the stability of the optical output, by setting a product of a coupling coefficient k and the grating length Lg to equal to or less than 0.3 (see Japanese Patent Application No. 2001-134545). When a cavity length L is 1300 micrometers, the cavity oscillates in a plurality of longitudinal modes when the grating length Lg does not exceed 300 micrometers. Therefore, it is preferable that the cavity length L is equal to or less than 300 micrometers. A longitudinal mode interval also changes in proportion to the cavity length L. Therefore, the grating length Lg is proportional to the cavity length L. In other words, to keep a relation (grating length Lg):(cavity length L)=300:1300, a relation that a plurality of longitudinal modes is obtained when the grating length Lg is not larger than 300 micrometers can be expanded as:

Lg×(1300 (micrometers)/L)<300 (micrometers).

The grating length Lg is set to maintain a ratio with the cavity length L, and is set to a value equal to or less than (300/1300) times the cavity length L (see Japanese Patent Application No. 2001-134545).

The semiconductor laser device according to the first embodiment has an oscillation wavelength So within a range between 1100 nanometers and 1550 nanometers, and has a cavity length L within a range between 800 micrometers and 3200 micrometers.

In general, when an effective refractive index is “n”, a longitudinal mode interval Δλ that the cavity of the semiconductor laser device generates is expressed as:

Δλ=λ₀²/(2·n·L).

When the oscillation wavelength λ₀ is 1480 micrometers, the effective refractive index n is 3.5, and the cavity length L is 800 micrometers, the longitudinal mode interval the Δλ is approximately 0.39 nanometer. When the cavity length L is 3200 micrometers, the Δλ in the longitudinal mode is approximately 0.1 nanometer. In other words, the longer the cavity length L is, the narrower the mode interval Δλ is. Consequently, a selection condition for oscillating the laser light in a single longitudinal mode becomes severer.

On the other hand, the grating 13 selects a longitudinal mode based on a Bragg wavelength. Wavelength selectivity of the grating 13 is expressed as an oscillation spectrum 16, as shown in FIG. 3. A plurality of longitudinal modes exists within the selected wavelength represented by a full width at half maximum (FWHM) Δλh of the oscillation spectrum 16 of the semiconductor laser device having the grating 13. Since a conventional distributed-Bragg-reflector (DBR) semiconductor laser device or a distributed-feedback (DFB) semiconductor laser device, when the cavity length L is 800 micrometers or longer, cannot make a single mode oscillation, a semiconductor laser device having a cavity length L longer than 800 micrometers has not been used for those types. However, the semiconductor laser device according to the first embodiment positively sets the cavity length L to 800 micrometers or longer to obtain a laser oscillation including a large number of longitudinal modes within the FWHM Δλh of the oscillation spectrum 16.

In general, the smaller the grating length Lg is, the broader the FWHM Δλh of the oscillation spectrum becomes. The number of longitudinal modes, each of which has an intensity difference equal to or less than 10 decibels from a maximum intensity, also increases. In order to select a desired longitudinal mode, it is necessary that a product of the coupling coefficient k and the grating length Lg exceeds a predetermined value. Under this condition, the number of longitudinal modes can be changed by changing the value of the grating length Lg.

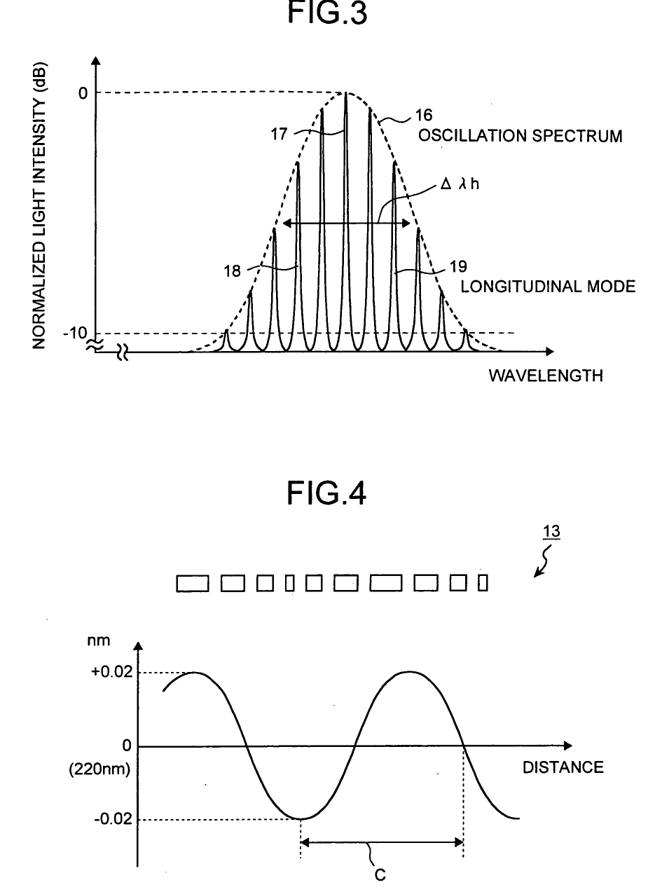

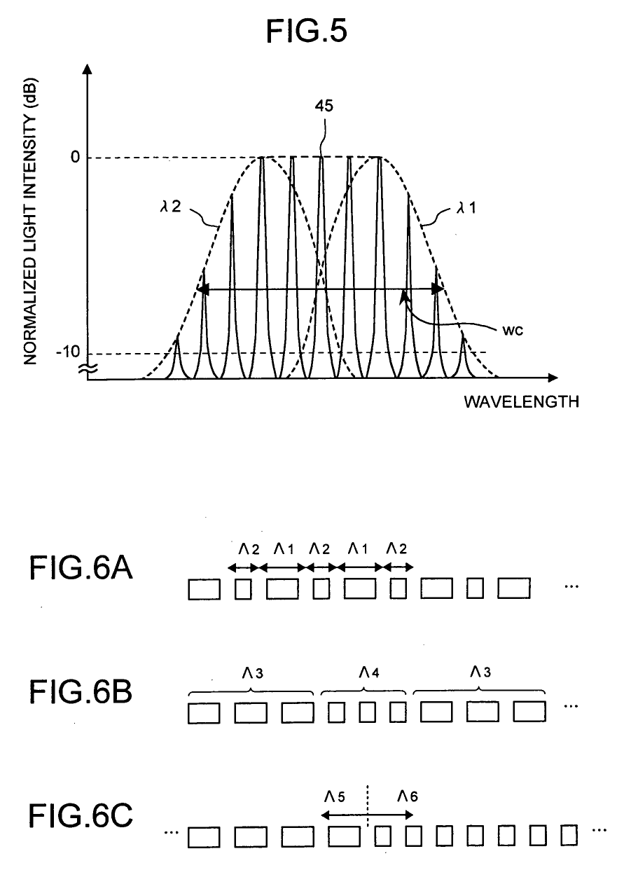

It is also effective to change a period of the grating 13. FIG. 4 is a graph of a chirped grating as an example that periodically changes the period of the grating 13. Accordingly, it is possible to generate a fluctuation in the wavelength selectivity of the grating, increase the FWHM Δλh of the oscillation spectrum, and change the number of longitudinal modes. In other words, as shown in FIG. 5, the number of longitudinal modes can be changed by expanding or narrowing the FWHM Δλh.

As shown in FIG. 4, the grating 13 has a structure having an average pitch of 220 nanometers, repeating a cyclic fluctuation (i.e., a deviation) of ±0.02 nanometer in a cycle of C. Based on the cyclic fluctuation, a reflection band of the grating 13 has an FWHM of about 2 nanometers. With this arrangement, it is possible to change the number of longitudinal modes, each of which has an intensity difference equal to or less than 10 decibels from a maximum intensity.

Although the example shown in FIG. 4 uses the chirped grating that changes the grating period in the constant cycle C, it is also possible to change the grating period at random between a period Λ₁ (220 nanometers +0.02 nanometer) and a period Λ₂ (220 nanometers −0.02 nanometer).

As shown in FIG. 6A, the grating may have a cyclic fluctuation that alternately repeats a period Λ₁ and a period Λ₂. As shown in FIG. 6B, the grating may have a cyclic fluctuation that alternately repeats a plurality of periods Λ₃ and a plurality of periods Λ₄. As shown in FIG. 6C, the grating may have a cyclic fluctuation that alternately repeats a continuous plurality of periods Λ₅ and a continuous plurality of periods Λ₆. Furthermore, it is also possible to dispose the grating by complementing periods having discrete values between periods Λ₁, Λ₃, and Λ₅, and periods Λ₂, Λ₄, and Λ₆.

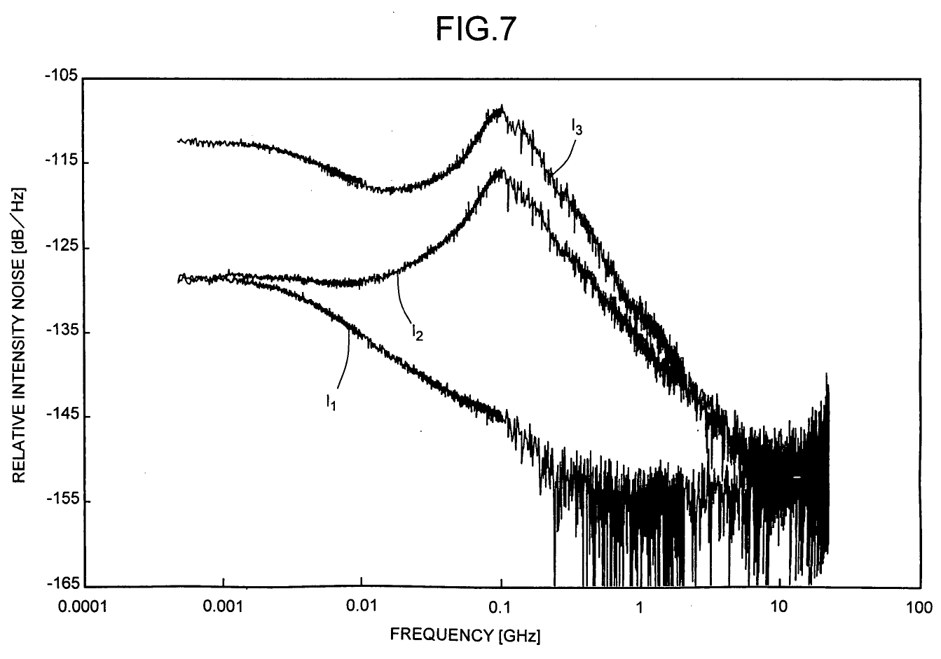

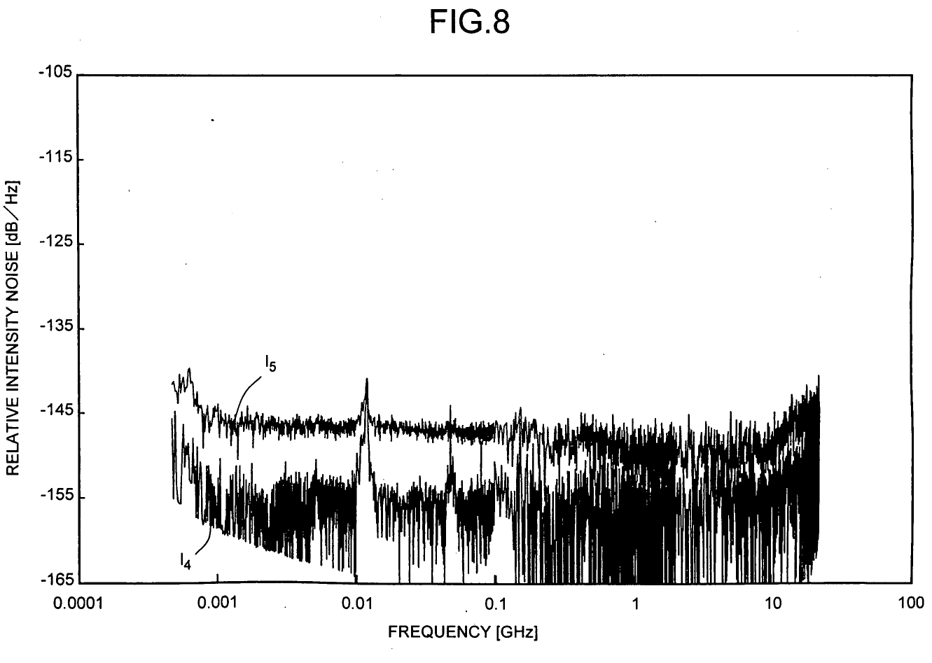

FIG. 7 to FIG. 9 illustrate a change in the relative intensity noise with a change of the number of longitudinal modes, each of which has an intensity difference equal to or less than 10 decibels from a maximum intensity. In order to change the number of longitudinal modes, a semiconductor laser device equipped with a Fabry-Perot cavity is used for the measurement corresponding to the graph of FIG. 7, and a DFB semiconductor laser device is used for the measurement corresponding to FIG. 8. However, a difference between the structures does not substantially affect results of the measurements.

In FIG. 7 to FIG. 9, three traces of the relative intensity noise were measured before transmitting a laser light through an optical fiber, after transmitting the laser light over a distance of 37 kilometers, and after transmitting the laser light over a distance of 74 kilometers, respectively. The optical fiber that was used to transmit the laser light is a TrueWave (R) RS fiber manufactured by Lucent Technologies, Inc. The optical fiber has a zero-dispersion wavelength at 1463 nanometers, a dispersion slope of 0.047 ps/nm²/km near the wavelength, and a mode field diameter of 8.5 micrometers at a wavelength of 1550 nanometers. The relative intensity noise is measured within a frequency range between 500 kilohertz and 22 gigahertz. Each semiconductor laser device that is used for the measurement in FIG. 7 to FIG. 9 has a buried heterostructure and a multiple quantum well grown by a metal organic chemical vapor deposition (MOCVD) method. Both the emission facet and the reflection facet have specific reflection coatings, respectively. A cavity length that is defined by a distance between the emission facet and the reflection facet is 1500 micrometers.

The graph in FIG. 7 is relative intensity noise characteristics of a laser light having 63 longitudinal modes, each of which has an intensity difference equal to or less than 10 decibels from a maximum intensity. A curve I₁ represents a trace of the relative intensity noise before the laser light is transmitted through the optical fiber. A curve I₂ and a curve I₃ represent traces of the relative intensity noise after a laser light is transmitted over the distance of 37 kilometers and the distance of 74 kilometers, respectively.

As is clear from FIG. 7, the relative intensity noise after the transmission shows a remarkable increase as compared with the relative intensity noise before the transmission. Particularly, the relative intensity noise increases remarkably in a low-frequency region up to about 1 gigahertz, and has a peak at a range between 0.1 and 0.2 gigahertz. As is clear from a comparison between the curve I₂ and the curve I₃, the relative intensity noise in the low-frequency region increases as the transmission distance increases.

FIG. 8 is a result of the relative intensity noise measurement for the DFB semiconductor laser device that outputs a single-mode laser light. A curve I₄ represents a trace of the relative intensity noise before transmitting the laser light, and a curve I₅ represents a trace of relative intensity noise after transmitting the laser light over the distance of 37 kilometers. The DFB semiconductor laser device has basically low output intensity. Therefore, the intensity of the laser light after the transmission over 74 kilometers is extremely lower than that of other semiconductor laser devices, and it is not possible to obtain reliable data about the relative intensity noise. A current that is injected to the DFB semiconductor laser device is 150 milliampere, and a center wavelength of the output laser light is 1547 nanometers.

Based on the result of the measurement shown in FIG. 8, the overall relative intensity noise in the DFB semiconductor laser device is suppressed to a low level, and there is little change in the relative intensity noise after the transmission. Unlike the semiconductor laser device using the Fabry-Perot cavity shown in FIG. 7, the relative intensity noise in the DFB semiconductor laser device does not increase in the low-frequency region, and a satisfactory value is maintained as a whole.

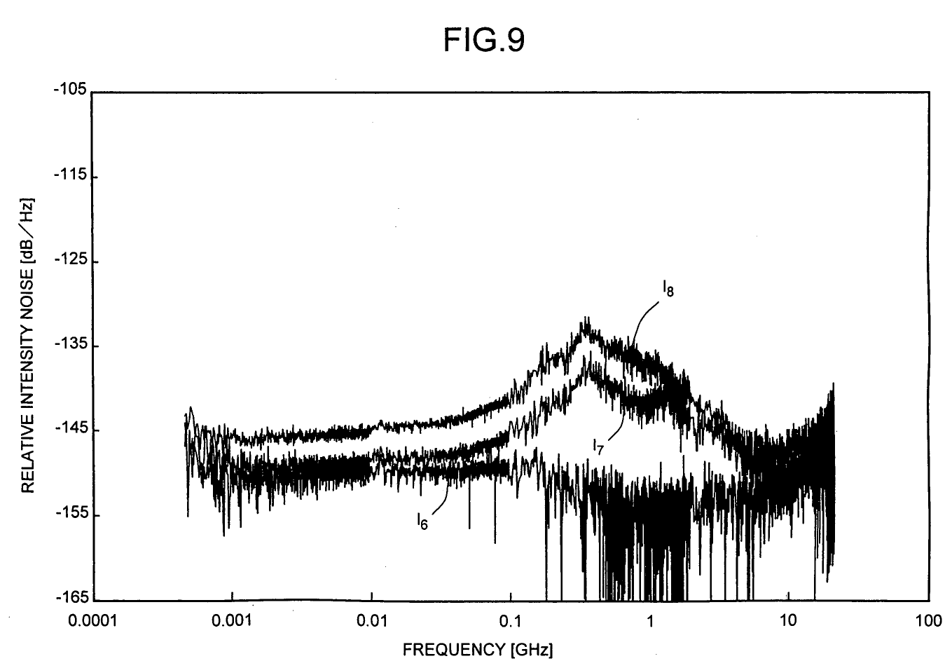

The semiconductor laser device that is used for the measurement shown in FIG. 9 has the grating adjacent to the active layer, thereby to output a light having a plurality of longitudinal modes. A current that is injected to the semiconductor laser device used for the measurement shown in FIG. 9 is 900 milliampere. A center wavelength of the output laser light is 1501 nanometers. A width of an envelope of a laser light at a portion where an intensity difference from a maximum intensity is equal to or less than 10 decibels is 3.4 nanometers. The number of longitudinal modes, each of which has an intensity difference equal to or less than 10 decibels from a maximum intensity, is eighteen.

In FIG. 9, a curve I₆ represents relative intensity noise characteristics before the transmission, and a curve I₇ and a curve I₈ show relative intensity noise characteristics after the transmission over the distance of 37 kilometers and the distance of 74 kilometers, respectively. As shown in FIG. 9, in comparing between the relative intensity noise before the transmission and that after the transmission, the relative intensity noise slightly increases in the frequency range from 0.3 gigahertz to 3 gigahertz. However, the increase in the relative intensity noise is suppressed to a low value in comparison with the increase shown in FIG. 7. Specifically, at 0.1 gigahertz, for example, a difference of relative intensity noise about 30 decibels to 35 decibels is observed between before and after the transmission in FIG. 7. However, in FIG. 9, the increase in the relative intensity noise is suppressed to about 5 decibels at most.

From the results of the measurements shown in FIG. 7 to FIG. 9, it is clear that suppressing the increase in the relative intensity noise after the transmission can be achieved, when the number of longitudinal modes, each of which has an intensity difference equal to or less than 10 decibels from a maximum intensity, is smaller. In the graphs shown in FIG. 7 to FIG. 9, the relative intensity noise before the transmission (as shown by the curves I₁, I₄, and I₆) is substantially the same. However, when the number of longitudinal modes, each of which has an intensity difference equal to or less than 10 decibels from a maximum intensity, is different, the relative intensity noise after the transmission greatly changes.

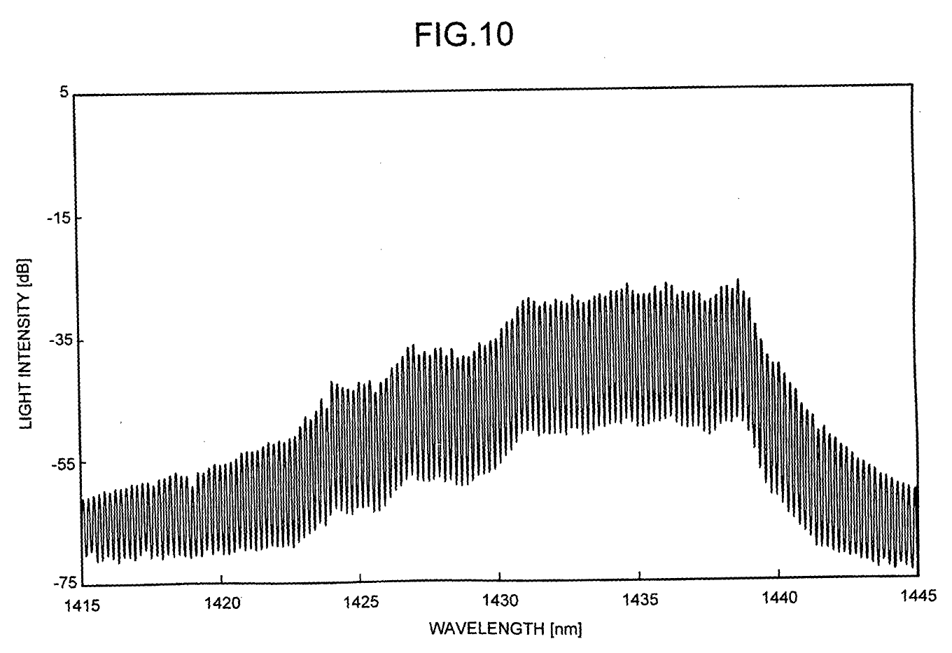

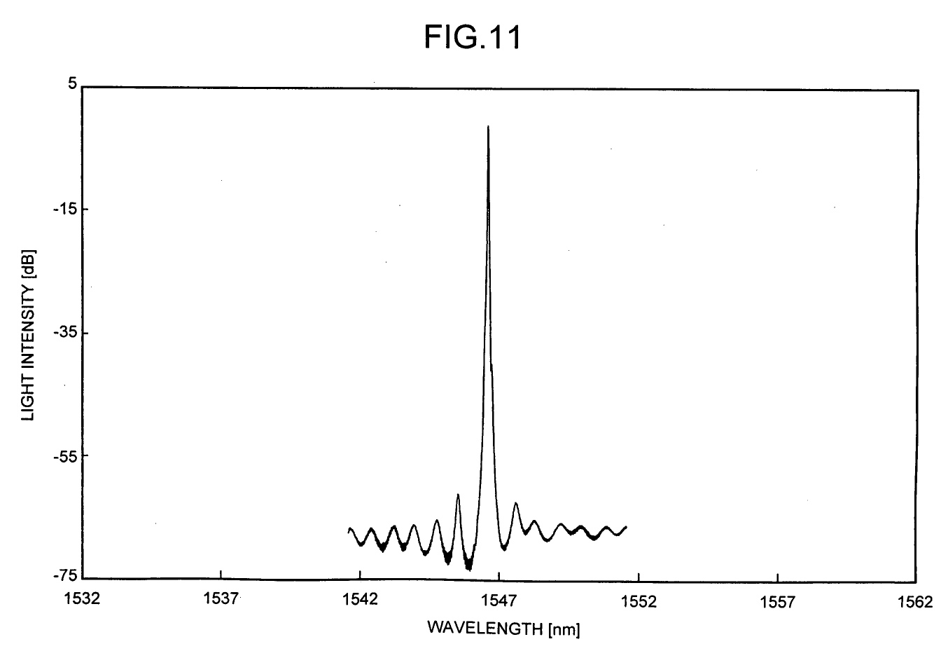

Oscillation spectra of the semiconductor laser devices used for the measuring in FIG. 7 to FIG. 9 are shown in FIG. 10 to FIG. 12, respectively. The graph shown in FIG. 10 is an illustration of oscillation spectrum of the laser light output from the semiconductor laser device used for the measurement shown in FIG. 7.

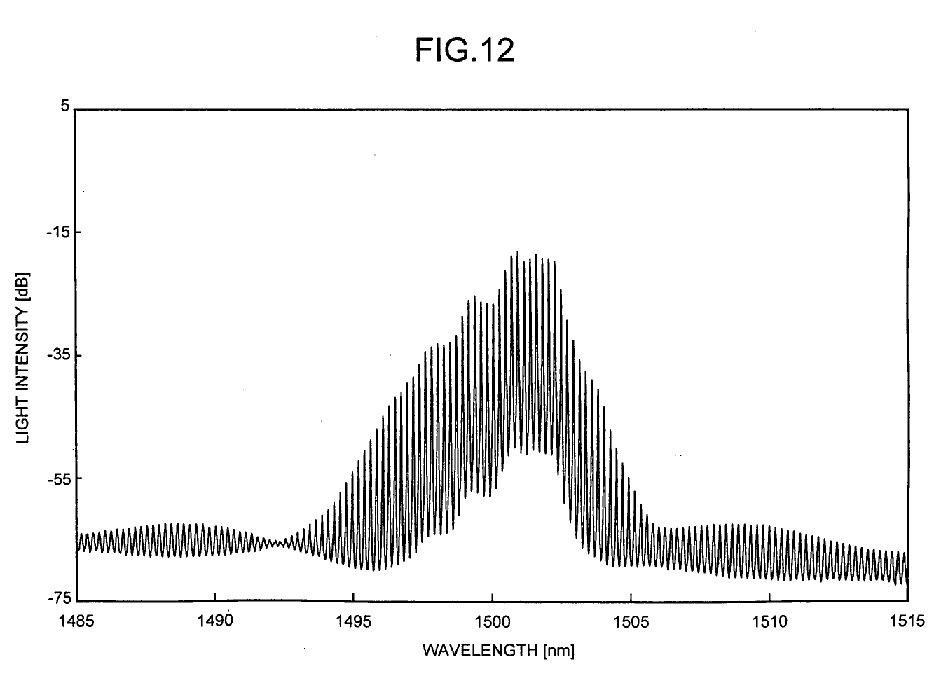

The semiconductor laser devices used for the measurement have different structures to select wavelengths of the output laser lights. As shown in FIG. 10, the semiconductor laser device having the Fabry-Perot cavity used for the measurement in FIG. 7 has a relatively mild envelope of the oscillation spectrum. On the other hand, the DFB semiconductor laser device used for the measurement shown in FIG. 8 has high intensity in only a single longitudinal mode, and has low intensity in other longitudinal modes, which is also in a small number. As shown in FIG. 12, the laser light output from the semiconductor laser device used for the measurement shown in FIG. 9 has the same number of longitudinal modes as that of the semiconductor laser device having the Fabry-Perot cavity shown in FIG. 10. However, the envelope has a sharp shape near the center wavelength, and has lower intensity at portions far from the center wavelength, as compared with the pattern in the graph shown in FIG. 10. Therefore, although the current injected to the semiconductor laser device used for the measurement shown in FIG. 7 is equal to the current injected to the semiconductor laser device used for the measurement shown in FIG. 9, the number of longitudinal modes having at least a predetermined intensity is different.

The reason why the intensity of relative intensity noise after a transmission over a long distance is different depending on the number of longitudinal modes having at least the predetermined intensity can be considered as follows. In a multimode laser that outputs a laser light having a plurality of longitudinal modes, there exists a mode partition noise. The mode partition noise is due to a phenomenon that photons generated by a stimulated emission are distributed at random to each longitudinal mode.

Immediately after the laser light is output from the semiconductor laser device, even if the light intensity in an individual longitudinal mode fluctuates at random, a sum of the light intensity of all longitudinal modes becomes a value that corresponds to a current injected to the semiconductor laser device, that is, the energy injected to the semiconductor laser device. In other words, as long as the injected energy is constant, the sum of light intensity of the longitudinal modes immediately after the output from the semiconductor laser device becomes always constant. A constant output without fluctuation is obtained from the semiconductor laser device, as a total output laser power.

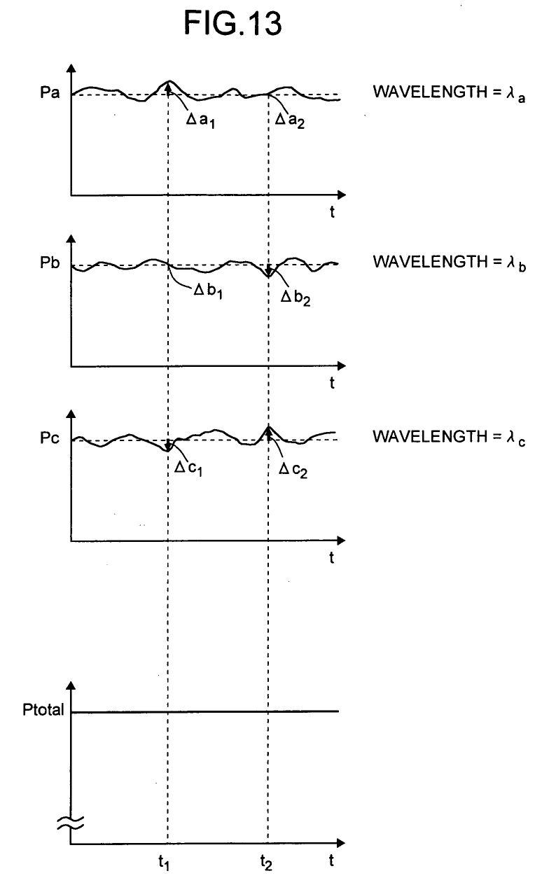

For example, FIG. 13 is an illustration of an example of fluctuations of light intensity for wavelengths λa, λb, and λc in a laser light having three longitudinal modes, and a fluctuation of light intensity for a sum of these wavelengths of the longitudinal modes. At time t₁, each longitudinal mode having the wavelengths λₐ, λ_{b}, and λ_{c} has a light intensity fluctuation of Δₐ₁, Δ_{b1}, and Δ_{c1}, respectively from average intensity in each longitudinal mode. The sum of these fluctuations (Δₐ₁+Δ_{b1}+Δ_{c1}) balances out the fluctuation from the average intensity, and becomes zero. At time t₂, the sum of fluctuations (Δₐ₂+Δ_{b2}+Δ_{c2}) of light intensity for a sum of the wavelengths λₐ, λ_{b}, and λ_{c} of the longitudinal modes balances out the fluctuation from the average intensity, and becomes zero. It is clear that, for the laser light immediately after the output from the semiconductor laser device, the sum of the light intensity of the longitudinal modes is held at a constant value, and the relative intensity noise becomes low.

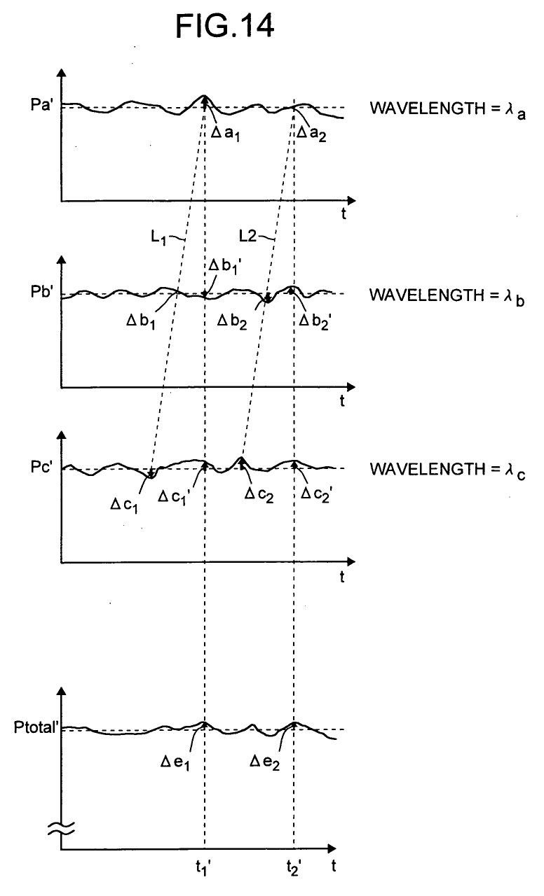

However, the laser light that is transmitted through the optical transmission line like the optical fiber receives an influence of wavelength dispersion in the optical transmission line. The propagation speed in each longitudinal mode is different depending on the wavelength, and a different delay occurs in each longitudinal mode. FIG. 14 is an illustration of a result that a laser light is transmitted through an optical fiber over a predetermined distance in each longitudinal mode shown in FIG. 13. As shown in FIG. 14, the propagation in the longitudinal mode having the wavelength λ_{b} is delayed from the propagation in the longitudinal mode having the wavelength λₐ. The propagation in the longitudinal mode having the wavelength λ_{c} is delayed from the propagation in the longitudinal mode having the wavelength λb. As a result, a sum of fluctuations (Δₐ₁′+Δ_{b1}′+Δ_{c1}′) from an average value of the light intensity for a sum of the wavelengths λₐ, λ_{b}, and λ_{c} of the longitudinal modes at time t₁′ does not become zero, and has a fluctuation Δₑ₁. Similarly, a sum of fluctuations (Δₐ₂′+Δ_{b2}′+Δ_{c2}′) at time t₂′ does not become zero, and has a fluctuation of Δₑ₂ different from Δₑ₁. As explained above, the relative intensity noise in the laser light that is transmitted through the optical transmission line varies with time, as the sum of fluctuations of the light intensity in the longitudinal modes does not become constant due to the wavelength dispersion.

In the multimode laser, it is considered that the relative intensity noise is increased after the transmission over a long distance increases due to the mode partition noise. In the mode partition noise, the fluctuation of the partition of the photon in each longitudinal mode is in a range up to about 1 gigahertz. Therefore, the relative intensity noise also increases in the low-frequency region of not larger than about 1 gigahertz. This is similar to a trend of the increase in the relative intensity noise shown in FIG. 7 and FIG. 9, which agrees with the increase in the relative intensity noise attributable to the mode partition noise. Furthermore, the fact that the relative intensity noise before the transmission is small and that the relative intensity noise increases after the transmission over a long distance becomes a collateral evidence that the relative intensity noise increases due to the mode partition noise.

In general, when the light intensity in the longitudinal mode is larger, the influence of the mode partition noise due to the increase in the relative intensity noise becomes larger. This is because an absolute value of a variation in the light intensity in the longitudinal mode having large light intensity is larger than a variation in the light intensity in the longitudinal mode having small light intensity. Therefore, the variation in the light intensity in the total laser light after the transmission over the predetermined distance becomes large.

In the multimode laser according to the present invention, the laser outputs a light having a plurality of longitudinal modes, the semiconductor laser device has not more than 60 longitudinal modes, each of which has an intensity difference equal to or less than 10 decibels from a maximum intensity. When the number of the longitudinal modes, each of which has an intensity difference equal to or less than 10 decibels from a maximum intensity, exceeds 60, the relative intensity noise after the transmission increases rapidly. Therefore, in the first embodiment, the number of longitudinal modes, each of which has the predetermined light intensity, is limited to 60. As is clear from the measurement results shown in FIG. 7 to FIG. 9, when the number of longitudinal modes, each on which has the predetermined light intensity, is smaller, the increase in the relative intensity noise can be suppressed. For example, when the number of longitudinal modes is fifty, it is possible to suppress the increase in the relative intensity noise more, comparing when the number of longitudinal modes is 60. By gradually decreasing the number of longitudinal modes, each of which has the predetermined light intensity, to forty and then to thirty, it becomes possible to suppress the increase in the relative intensity noise after the transmission.

As explained above, in the multimode laser that outputs a laser light having a plurality of longitudinal modes, it is possible to suppress the increase in the relative intensity noise due to the transmission over a long distance by setting the number of longitudinal modes equal to or less than 60, each of which has an intensity difference equal to or less than 10 decibels from a maximum intensity. The semiconductor laser device has a great advantage when, for example, the semiconductor laser device is used as a pump source for an optical fiber amplifier that utilizes the Raman amplification. In the Raman amplification, the Raman gain fluctuates corresponding to the fluctuation in the pump light. Therefore, the suppression of the relative intensity noise leads to the suppression of the fluctuation in the amplified signal light, which makes it possible to obtain a stable Raman amplification.

In the first embodiment, the grating 13 controls the number of longitudinal modes each of which has the predetermined intensity. What is important in the present invention is the number of longitudinal modes each of which has the predetermined intensity, and not the structure of the semiconductor laser device. Therefore, even when the semiconductor laser device that employs a different structure than the above, such as a Fabry-Perot cavity, is used, it is sufficient if longitudinal modes equal to or less than 60 are used, each of which has an intensity difference equal to or less than 10 decibels from a maximum intensity. Particularly, in recent years, the semiconductor laser device employing the Fabry-Perot cavity that has a predetermined active layer and that has an optical cavity formed between the emission facet and the reflection facet is considered promising for application as the pump source in the Raman amplifier that employs a co-propagating pumping system. Therefore, using the semiconductor laser device having a limited number of longitudinal modes is used, since the relative intensity noise becomes small, the intensity of the pumped signal light has little fluctuation, and thereby it possible to obtain a stable Raman amplification.

Furthermore, the semiconductor laser device may take an inversed-conductivity type structure, a ridge structure, or a self aligned structure (SAS), instead of the buried heterostructure (BH) shown in FIG. 1. The location of the grating 13 is not limited to the upper region of the GRIN-SCH-MQW active layer 3, and the grating 13 may be located on the lower region. In principle, the grating 13 can be disposed in any region as long as a laser oscillation light is distributed in the region. A grating may be disposed on the whole surface or partially for the width in the horizontal direction of the grating 13. The active layer needs not necessarily have the GRIN-SCH-MQW structure, and may have a simple double heterostructure, or may be a homo-junction laser. Instead of the multiple quantum well structure, a single quantum well structure may be used.

The semiconductor laser module according to a second embodiment of the present invention is a module in which the semiconductor laser device explained in the first embodiment is mounted.

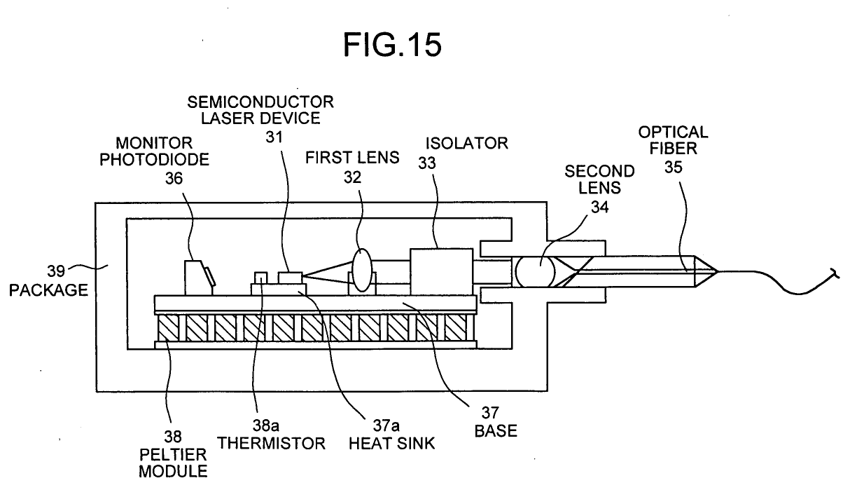

FIG. 15 is a side cross-sectional view of a structure of the semiconductor laser module according to the second embodiment. The semiconductor laser module has a semiconductor laser device 31 that corresponds to the semiconductor laser device explained in the first embodiment. The semiconductor laser module has a package 39 of which the case is made of Cu—W alloy or the like. A Peltier device 38 is disposed as a temperature controller on the internal bottom surface of the package 39. A base 37 is disposed on the Peltier device 38. A heat sink 37a is disposed on the base 37. A current is given to the Peltier device 38, which operates as a cooler or a heater based on the polarity of the current. In order to prevent a shift of the oscillation wavelength due to a temperature rise of the semiconductor laser device 31, the Peltier device 38 mainly functions as a cooler. In other words, when a laser light has a wavelength longer than a desired wavelength, the Peltier device 38 cools the semiconductor laser device to a low temperature. When a laser light has a wavelength shorter than a desired wavelength, the Peltier device 38 heats the semiconductor laser device to a high temperature. A controller (not shown in the figure) controls the Peltier device 38 to control the temperature based on a detection value of a thermistor 38a disposed adjacent to the semiconductor laser device 31 on the heat sink 37a. The controller controls the Peltier device 38 to keep the temperature of the heat sink 37a constant. When the drive current of the semiconductor laser device 31 increases, the controller controls the Peltier device 38 to lower the temperature of the heat sink 37a. By controlling the temperature, it is possible to improve the wavelength stability of the semiconductor laser device 31. It is preferable that the heat sink 37a is formed with a material having a high thermal conductivity such as diamond. When the heat sink 37a is formed with diamond, the heating at the time of injecting a high current can be suppressed. In this case, the wavelength stability further improves, and it becomes easy to control the temperature.

The heat sink 37a, on which the semiconductor laser device 31 and the thermistor 38a are disposed, a first lens 32, and a monitor photodiode 36 are disposed on the base 37. A laser light emitted from the semiconductor laser device 31 is guided into an optical fiber 35 via the first lens 32, an isolator 33, and a second lens 34. The second lens 34 is provided on the package 39 on an optical axis of the laser light, and is optically coupled with the optical fiber 35. The monitor photodiode 36 detects a light from the reflection coating side of the semiconductor laser device 31.

In the semiconductor laser module, the isolator 33 is provided between the semiconductor laser device 31 and the optical fiber 35 in order to prevent a reflected light from other optical part from being input to the cavity. For this isolator 33, a compact polarizing isolator can be used instead of an inline non-polarizing isolator. Therefore, the insertion loss due to the isolator can be minimized, permitting the cost to be lower.

Furthermore, in order to prevent a reflection light from a facet of the optical fiber 35 from being input to the semiconductor laser device 31, it is preferable that the facet of the optical fiber 35 is tilted so that the light is incident on the facet of the optical fiber at an oblique angle.

Since the semiconductor laser module according to the second embodiment is a module in which the semiconductor laser device according to the first embodiment is mounted, it is possible to output a laser light having equal to or less than 60 longitudinal modes. Therefore, it is capable of suppressing an increase in relative intensity noise attributable to the mode partition noise even after the transmission over a long distance.

In a third embodiment of the present invention, the semiconductor laser module according to the second embodiment is applied to a Raman amplifier.

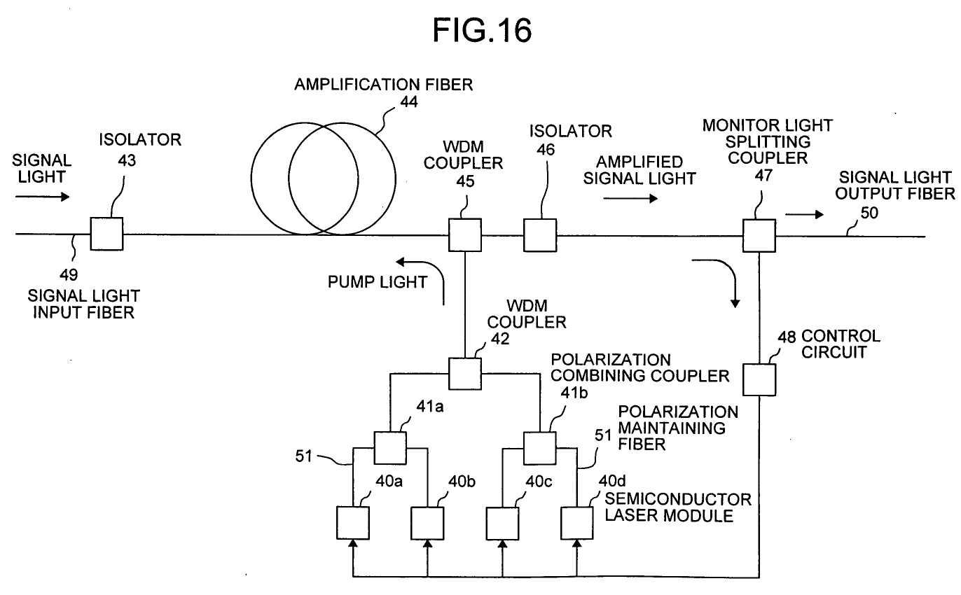

FIG. 16 is a block diagram of a structure of the optical fiber amplifier according to the third embodiment. This Raman amplifier is used for the wavelength division multiplexing (WDM) communication system.

The semiconductor laser modules 40a and 40b output a laser light having a plurality of longitudinal modes to a polarization combining coupler 41a via a polarization maintaining fiber 51. The semiconductor laser modules 40c and 40d output a laser light having a plurality of longitudinal modes to a polarization combining coupler 41b via the polarization maintaining fiber 51. The wavelengths of the laser lights from the semiconductor laser modules 40a and 40b are identical. The wavelengths of the laser lights from the semiconductor laser modules 40c and 40d are identical, which are different from the wavelengths of the laser lights from the semiconductor laser modules 40a and 40b. This is because the Raman amplification has a polarization dependency. The polarization combining couplers 41a and 41b output a light that is polarization-independent.

A WDM coupler 42 combines the laser lights having different wavelengths that are output from the polarization combining couplers 41a and 41b. The WDM coupler 42 outputs a combined result of the laser lights to an amplification fiber 44 as a pump light for Raman amplification, via the WDM coupler 45. A signal light to be amplified is input to the amplification fiber 44 to which the pump light is input. The amplification fiber 44 amplifies the signal light based on the Raman amplification.

The amplified signal light is input to a monitor light splitting coupler 47 via the WDM coupler 45 and an isolator 46. The monitor light splitting coupler 47 outputs a part of the amplified signal light to a control circuit 48, and the rest of the amplified signal light to a signal optical output fiber 50 as an output light.

The control circuit 48 controls a laser output state, for example, light intensity, of each of the semiconductor laser modules 40a to 40d based on the input part of the amplified signal, and feedback controls so that the gain zone of the Raman amplification becomes flat.

The Raman amplifier in the third embodiment uses the semiconductor laser module 40a that incorporates the semiconductor laser device explained in the first embodiment. As explained above, each of the semiconductor laser modules 40a to 40d has a plurality of longitudinal modes. Therefore, the length of the polarization maintaining fiber can be shortened. As a result, a reduction in the weight and a reduction in the cost of the Raman amplifier can be realized.

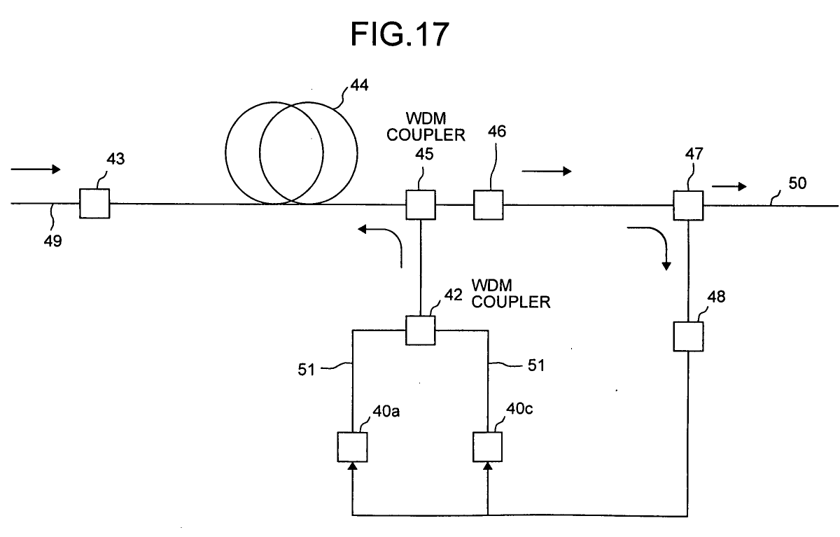

While the Raman amplifier shown in FIG. 16 uses the polarization combining couplers 41a and 41b, it is also possible to arrange such that the semiconductor laser modules 40a and 40c directly output lights to the WDM coupler 42 via the polarization maintaining fiber 51 respectively as shown in FIG. 17. In this case, laser lights are incident such that the polarization planes of the semiconductor laser modules 40a and 40c are at forty-five degrees relative to the polarization maintaining fiber 51. As each of the semiconductor laser modules 40a and 40c has a plurality of longitudinal modes, the length of the polarization maintaining fiber can be shortened, as explained above. Therefore, it is possible to avoid the polarization dependency of the optical output from the polarization maintaining fiber 51, leading to a realization of a compact Raman amplifier having a small number of parts.

When a semiconductor laser device having a plurality of longitudinal modes is used as the semiconductor laser device that is incorporated in each of the semiconductor laser modules 40a to 40d, the necessary length of the polarization maintaining fiber 51 can be shortened. Particularly, when the number of longitudinal modes becomes four or five, the necessary length of the polarization maintaining fiber 51 becomes drastically short. Therefore, a simplification and a reduction in size of the Raman amplifier can be promoted. When the number of longitudinal modes increases, the coherent length becomes short, and the degree of polarization (DOP) becomes small based on a depolarization. As a result, it is possible to avoid the polarization dependency, which can further promote a simplification and a reduction in size of the Raman amplifier.

Since it is easy to align the optical axis, and there is no mechanical optical coupling within the cavity, it is also possible to increase stability and reliability of the Raman amplification.

The semiconductor laser device explained in the first embodiment has equal to or less than 60 longitudinal modes, each of which has an intensity difference equal to or less than 10 decibels from a maximum intensity. Therefore, even when a pump light is transmitted over a long distance within the Raman amplifier, an increase in the relative intensity noise attributable to the mode partition noise can be suppressed, and a stable Raman gain can be obtained.

The Raman amplifiers shown in FIG. 16 and FIG. 17 are based on a counter-propagating pumping system. As the semiconductor laser modules 40a to 40d output stable pump lights, it is also possible to obtain a stable Raman amplification when the Raman amplifiers are based on a co-propagating pumping system or a bidirectional pumping system.

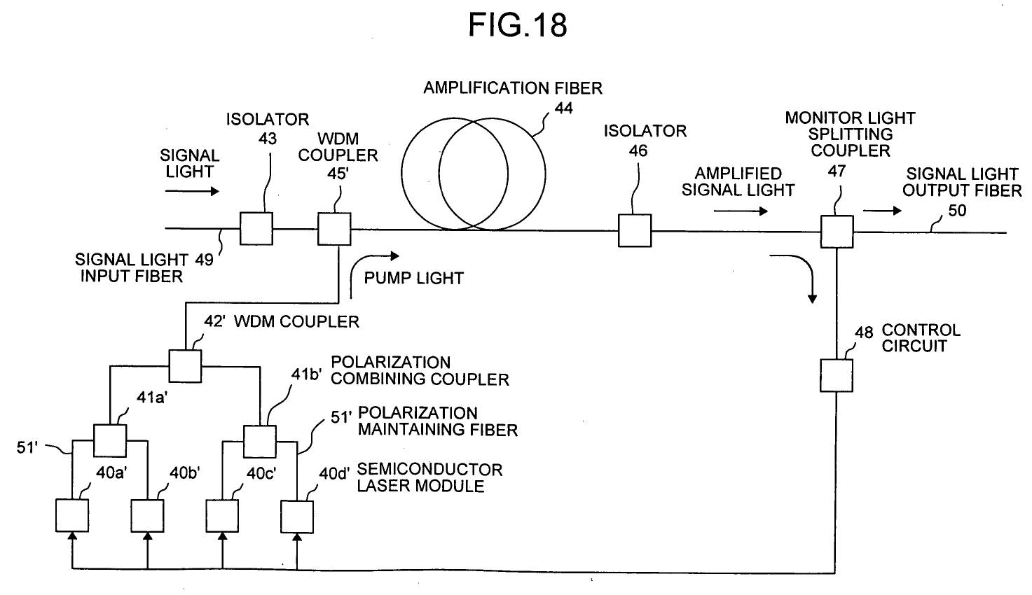

For example, FIG. 18 is a block diagram of a structure of the Raman amplifier employing the co-propagating pumping system. The Raman amplifier shown in FIG. 18 has a WDM coupler 45′ provided adjacent to the isolator 43 in the Raman amplifier shown in FIG. 16. To this WDM coupler 45′, a circuit, which includes the polarization combining couplers 41a′ and 41b′, and the semiconductor laser modules 40a′ to 40d′, and the WDM coupler 42′, is connected. The WDM coupler 45′ carries out a co-propagating pumping of outputting the pump light output from the WDM coupler 42′ to the same direction as that for the signal light. In this case, the semiconductor laser modules that are used in the second embodiment are used for the semiconductor laser modules 40a′ to 40d′. Therefore, relative intensity noise is small, which makes it possible to effectively carry out the co-propagating pumping.

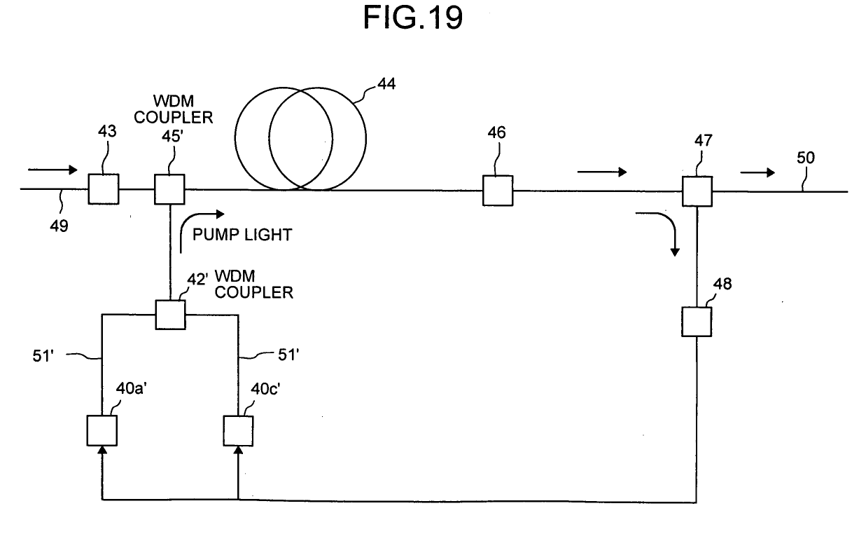

Similarly, FIG. 19 is a block diagram of a structure of the Raman amplifier employing the co-propagating pumping system. The Raman amplifier shown in FIG. 19 has a WDM coupler 45′ provided adjacent to the isolator 43 in the Raman amplifier shown in FIG. 17. To this WDM coupler 45′, a circuit, which includes the semiconductor laser modules 40a′ and 40c′, and a WDM coupler 42′, is connected. The WDM coupler 45′ carries out a co-propagating pumping of outputting the pump light output from the WDM coupler 42′ to the same direction as that for the signal light. In this case, the semiconductor laser modules that are used in the second embodiment are used for the semiconductor laser modules 40a′ and 40c′. Therefore, the relative intensity noise is small, which makes it possible to effectively carry out the co-propagating pumping.

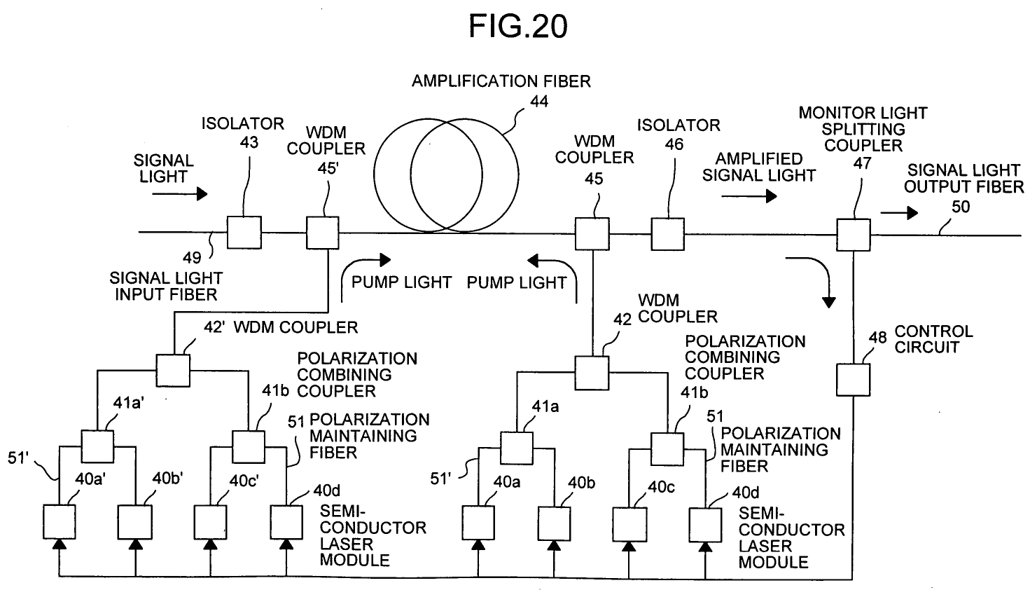

FIG. 20 is a block diagram of a structure of a Raman amplifier employing the bidirectional pumping system. The Raman amplifier shown in FIG. 20 additionally has the WDM coupler 45′, the semiconductor laser modules 40a′ to 40d′, the polarization combining couplers 41a′ and 41b′, and the WDM coupler 42′ shown in FIG. 18, in the structure of the Raman amplifier shown in FIG. 16. Based on this structure, the Raman amplifier carries out both the counter-propagating pumping and the co-propagating pumping. In this case, the semiconductor laser modules that are used in the second embodiment are used for the semiconductor laser modules 40a′ to 40d′. Therefore, the relative intensity noise is small, which makes it possible to effectively carry out the co-propagating pumping.

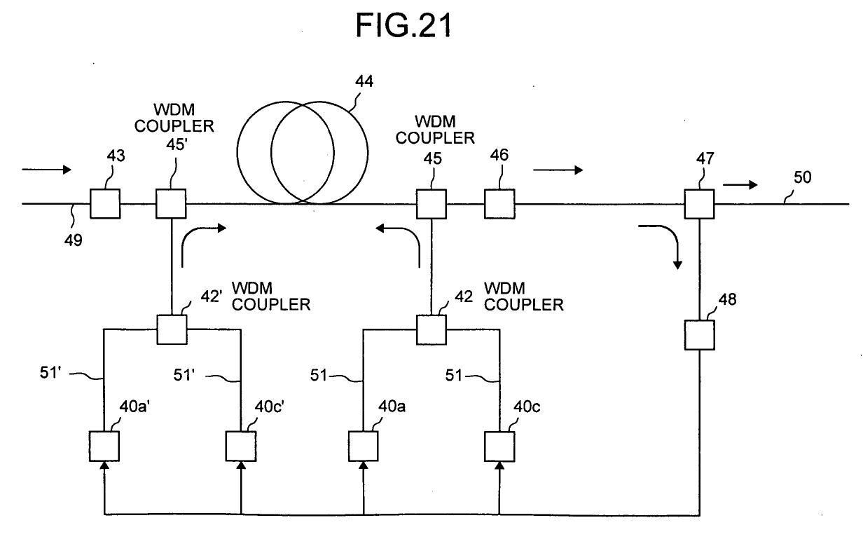

Similarly, FIG. 21 is a block diagram of a structure of another Raman amplifier employing the bidirectional pumping system. The Raman amplifier shown in FIG. 21 additionally has the WDM coupler 45′, the semiconductor laser modules 40a′ and 40c′, and the WDM coupler 42′ shown in FIG. 19, in the structure of the Raman amplifier shown in FIG. 17. Based on this structure, the Raman amplifier carries out both the counter-propagating pumping and the co-propagating pumping. In this case, the semiconductor laser modules that are used in the second embodiment are used for the semiconductor laser modules 40a′ and 40c′. Therefore, the relative intensity noise is small, which makes it possible to effectively carry out the co-propagating pumping.

In the Raman amplification light source that is used for the co-propagating pumping, the cavity length L may be less than 800 micrometers. When the cavity length L is less than 800 micrometers, the mode interval Δλ in the longitudinal mode becomes short. When the mode interval is short, the number of longitudinal modes becomes small, and it becomes impossible to obtain a sufficient optical output. However, since the co-propagating pumping requires a lower output than the counter-propagating pumping, it is not always necessary that the cavity length L is 800 micrometers or longer.

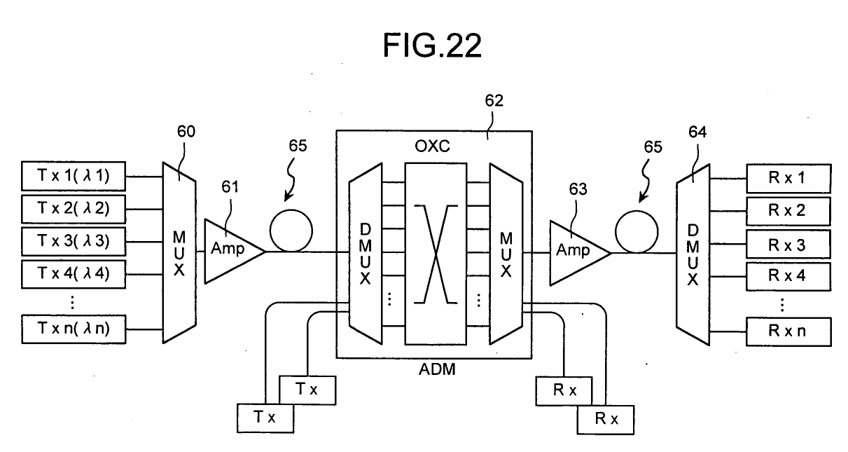

The Raman amplifiers shown in FIG. 16 to FIG. 21 can be applied to the WDM communication system. FIG. 22 is a block diagram of a schematic structure of the WDM communication system to which the Raman amplifier is applied.

An optical multiplexer 60 multiplexes optical signals having wavelengths λ1 to λn that are transmitted from a plurality of transmitters Tx1 to Txn, and integrates multiplexed signals into one optical fiber 65. A plurality of Raman amplifiers 61 and 63 corresponding to the Raman amplifiers shown in FIG. 16 to FIG. 21 are disposed with a distance between them on a transmission line of the optical fiber 65, and amplify attenuated optical signals. An optical demultiplexer 64 demultiplexes the signal transmitted through the optical fiber 65 into optical signals having the wavelengths λ1 to λn. A plurality of receivers R×1 to R×n receives these optical signals. In some cases, an add/drop multiplexer (ADM) that adds or drops an optical signal of an optional wavelength is inserted into the optical fiber 65.

In the third embodiment, the semiconductor laser device explained in the first embodiment or the semiconductor laser module explained in the second embodiment is used as the pump source for Raman amplification. It is apparent that the application is not limited to this, and it is also possible to use the semiconductor laser device or the semiconductor laser module as an erbium-doped fiber amplifier (EDFA) pump source of 0.98 micrometer.

In a fourth embodiment of the present invention, one of techniques for suppressing the stimulated Brillouin scattering is used to suppress the relative intensity noise. A bias current to the semiconductor laser device is modulated to output a modulated laser light. The inventors of the present invention first found that it is possible to suppress the relative intensity noise by suppressing the stimulated Brillouin scattering. When the semiconductor laser device is used as a pump source for a distribution-type amplifier such as the Raman amplifier, it is preferable to increase the pump light output in order to increase the amplification gain. However, when a peak output value is large, the stimulated Brillouin scattering occurs, and noise increases.

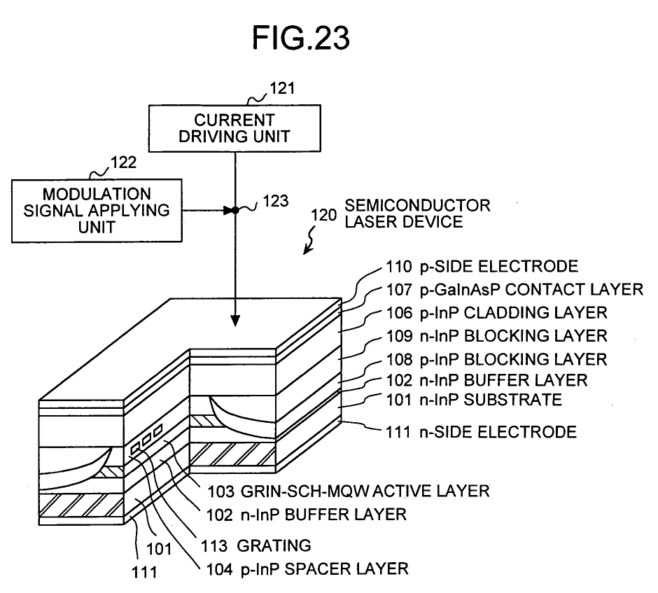

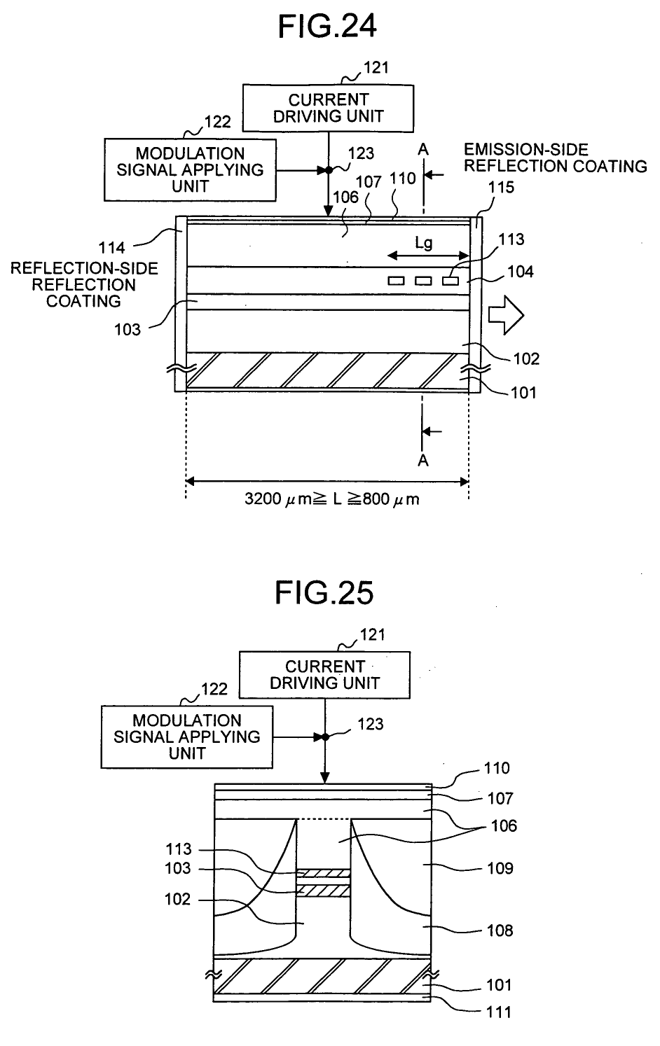

FIG. 23 is a cross-section of the semiconductor laser device according to the fourth embodiment. FIG. 24 is a schematic diagram of the semiconductor laser device shown in FIG. 23. FIG. 25 is a cross-section view of the semiconductor laser device shown in FIG. 24 cut along a line A-A. In FIG. 23 to FIG. 25, a semiconductor laser device 120 has such a structure that, on the plane (100) of an n-InP substrate 101, an n-InP buffer layer 102 that works as a buffer layer and a lower cladding layer of n-InP, a graded index-separate confinement heterostructure multiple quantum well (GRIN-SCH-MQW) active layer 103, a p-InP spacer layer 104, a p-InP cladding layer 106, and a p-InGaAsP contact layer 107 are sequentially grown.

In the p-InP spacer layer 104, there is a grating 113 having a film thickness of 20 nanometers, and a length Lg of 50 micrometers from a reflection facet of the emission-side reflection coating 115 toward a reflection coating 114. A plurality of the gratings 113 are formed periodically with a pitch of about 220 nanometers. Each grating 113 selects a wavelength of a laser light having a center wavelength of 1.48 micrometers. The grating 113 provides a satisfactory linearity of light-current characteristics, and improves the stability of the optical output, by setting a product of a coupling coefficient k and the grating length Lg to equal to or less than 0.3 (see Japanese Patent Application No. 2001-134545). When a cavity length L is 1300 micrometers, the cavity oscillates in a plurality of longitudinal modes when the grating length Lg is not longer than about 300 micrometers. Therefore, it is preferable that the cavity length L is not longer than 300 micrometers. A longitudinal mode interval also changes in proportion to the cavity length L. Therefore, the grating length Lg is proportional to the cavity length L. In other words, a relation that a ratio of the (grating length Lg) to the (cavity length L) is equal to 300 to 1300 is maintained. Consequently, a relation that a plurality of longitudinal modes is obtained when the grating length Lg is not larger than 300 micrometers can be expanded as follows.

Lg×(1300 (micrometers)/L)<300 (micrometers)

In other words, the grating length Lg is set to maintain a ratio with the cavity length L, and is set to a value not larger than (300/1300) times the cavity length L (refer to Japanese Patent Application No. 2001-134545). The p-InP spacer layer that includes the grating 113, the GRIN-SCH-MQW active layer 103, and an upper portion of the n-InP buffer layer 102 are formed in a mesa stripe shape. A p-InP blocking layer 108 and an n-InP blocking layer 109 are embedded on both sides of the mesa stripe in its longitudinal direction. A p-side electrode 110 is formed on the upper surface of the p-InGaAsP contact layer 107. An n-side electrode 111 is formed on the reverse side of the n-InP substrate 101. It is sufficient that a laser light output from the semiconductor laser device 120 oscillates in a single lateral mode. A structure of an active layer or an optical waveguide is not limited to a stripe structure.

On a light reflection facet as one facet of the semiconductor laser device 120 in its longitudinal direction, there is formed a reflection coating 114 having a light reflectivity of 80% or higher, preferably 98% or higher. On a light emission facet as the other facet of the semiconductor laser device 120, there is formed a light emission-side reflection coating 115 having a light reflectivity of not higher than 10%, preferably not higher than 5%, 1%, or 0.5% respectively, and more preferably not higher than 0.1%. The reflection coating 114 reflects a light that is generated within the GRIN-SCH-MQW active layer 103 of the optical cavity formed between the reflection coating 114 and the light emission-side reflection coating 115. This light is emitted as a laser light via the light emission-side reflection coating 115. In this case, the grating 113 selects a wavelength and emits the light.

This semiconductor laser device 120 has a current driving unit 121 that applies a bias current to the p-side electrode 110, and a modulation signal applying unit 122 that applies a modulation frequency signal for modulating the bias current. The modulation frequency signal output from the modulation signal applying unit 122 is superimposed on the bias current at a contact point 123. The superimposed signal having the modulation frequency signal superimposed is applied to the p-side electrode 110.

This modulation frequency signal is a sinusoidal wave signal of 5 to 1000 kilohertz, and has an amplitude of about 0.1 to 10% of the bias current. In other words, the modulation frequency signal is modulated to about ±10% of the bias current. It is not always necessary to define the modulation of the laser light such that the modulation frequency signal has the amplitude of about 0.1 to 10% of the bias current. It is also possible to define the modulation such that the modulation frequency signal has the amplitude of about 0.1 to 10% of the optical output. Further, the modulation frequency signal is not limited to the sinusoidal wave signal, but may be a periodical signal of a triangular wave signal. In this case, other periodical signal such as the triangular wave signal includes a plurality of sinusoidal wave components. Therefore, it is preferable to use a sinusoidal wave signal for the modulation frequency signal.

The semiconductor laser device 120 according to the fourth embodiment is based on the assumption that it is used as a pump source for a Raman amplifier. The semiconductor laser device 120 has an oscillation wavelength λ₀ within a range from 1100 nanometers to 1550 nanometers, and has a cavity length L within a range from 800 micrometers or larger to not larger than 3200 micrometers. In general, when an effective refractive index is expressed as “n”, a mode interval Δλ in the longitudinal mode that the cavity of the semiconductor laser device generates can be expressed as follows.

Δλ=λ₀²/(2·n·L)

When the oscillation wavelength λ₀ is 1480 micrometers, when the effective refractive index n is 3.5, and also when the cavity length L is 800 micrometers, the Δλ in the longitudinal mode becomes approximately 0.39 nanometer. When the cavity length L is 3200 micrometers, the Δλ in the longitudinal mode becomes approximately 0.1 nanometer. In other words, when the cavity length L is larger, the mode interval Δλ in the longitudinal mode becomes smaller. Consequently, a selective condition for oscillating the laser light in a single longitudinal mode becomes severer.

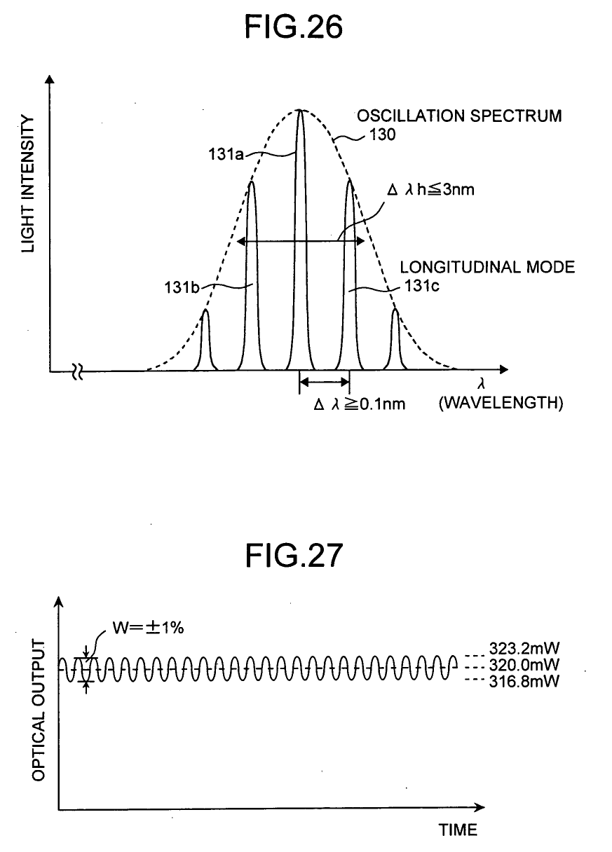

On the other hand, the grating 113 selects a longitudinal mode based on a Bragg wavelength. Selective wavelength characteristics of the grating 113 are expressed as an oscillation spectrum 130 as shown in FIG. 26.

As shown in FIG. 26, according to the fourth embodiment, a plurality of longitudinal modes exists within the selective wavelength characteristics as represented by a FWHM Δλh of the oscillation spectrum 130 of the semiconductor laser device 120 having the grating 113. According to the conventional DBR (distributed Bragg reflector) semiconductor laser device or DFB semiconductor laser device, when the cavity length L is 800 micrometers or larger, it is difficult to carry out the oscillation in the single longitudinal mode. Therefore, a semiconductor laser device having this cavity length L has not been used. However, the semiconductor laser device 120 according to the fourth embodiment positively sets the cavity length L to 800 micrometers or larger, thereby to carry out a laser oscillation by including a large number of longitudinal modes within the FWHM Δλh of the oscillation spectrum 130. In FIG. 26, within the FWHM Δλh of the oscillation spectrum, three longitudinal modes 131a to 131c are included.

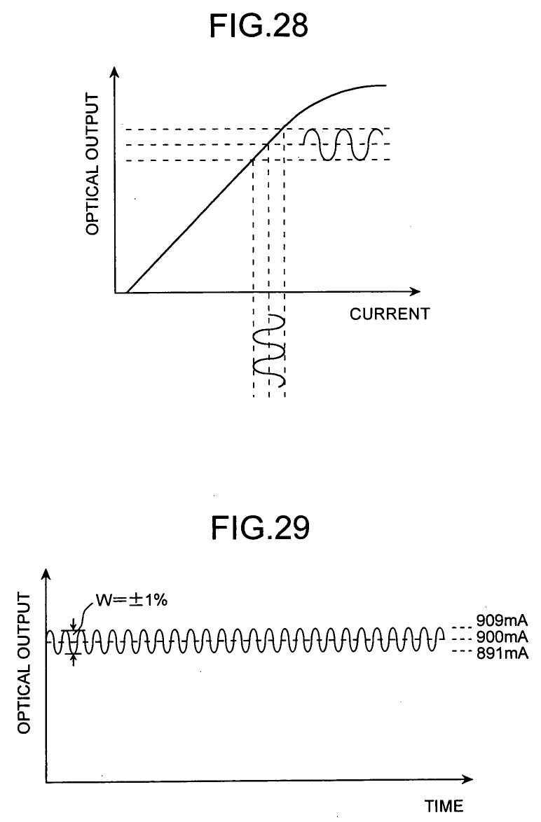

The spectrum width in each of the longitudinal modes 131a to 131c shown in FIG. 26 is larger than that when the semiconductor laser device is driven based on only the bias current output from the current driving unit 121. This is because the spectrum width is made larger based on the modulation frequency that is output from the modulation signal applying unit 122. FIG. 27 is a graph of a time change in an optical output when the modulation frequency signal is superimposed on the bias signal. In FIG. 27, the modulation frequency signal is a sinusoidal wave signal having an amplitude of 1% of the bias current. The amplitude of the optical output when the semiconductor laser device is driven based on only the bias current is sinusoidally changed by 1%. This operation corresponds to a modulation of current-optical output (I-L) characteristics of the semiconductor laser device as shown in FIG. 28.

In the modulation region shown in FIG. 28, the (I-L) characteristics are linear. Therefore, the modulation factor of the drive current modulated based on the modulation frequency signal directly becomes the modulation factor of the optical output. Consequently, in this modulation region, the modulation factor of the optical output is always maintained at 1%, based on the application of the drive current that maintains the amplitude of the modulation frequency at 1%, as shown in FIG. 29. As a result, it becomes easy to control the modulation factor of the optical output. On the other hand, in the region where the optical output further increases, the modulation factor of the drive current modulated based on the modulation frequency signal and the modulation factor of the optical output do not coincide with each other. In this case, the amplitude of the modulation frequency signal is adjusted so that the modulation factor of the optical output always becomes 1% as shown in FIG. 27.

As explained above, when the drive current applied to the semiconductor laser device changes, the effective refractive index “n”of the laser light in the light emission region such as the GRIN-SCH-MQW active layer 103 changes. When the effective refractive index “n” changes, an optical cavity length Lop also changes. In other words, when the physical cavity length is “L”, the optical cavity length Lop is expressed as follow.

Lop=n·L

Following the change in the effective refractive index “n”, the optical cavity length Lop changes. When the optical cavity length Lop changes, the cavity length also changes in the Fabry-Perot mode. In other words, the cavity length also changes sinusoidally.

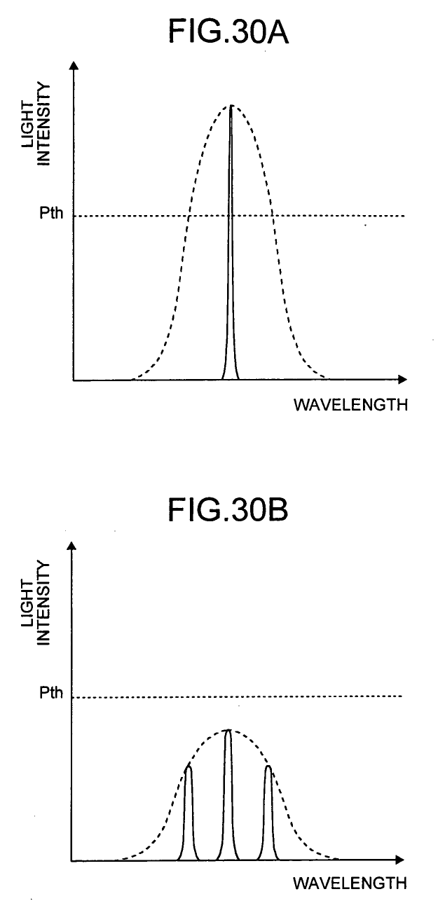

The change in the wavelength corresponding to the change in the current increases the spectrum width in the longitudinal mode as a result. FIGS. 30A and 30B are graphs of a spectrum waveform in the longitudinal mode of the DFB type semiconductor laser device on which the modulation frequency signal is not superimposed, and a spectrum waveform in the longitudinal mode of the semiconductor laser device according to the fourth embodiment on which the modulation frequency signal is superimposed. FIG. 30A is a graph of a spectrum waveform in the longitudinal mode of the DFB type semiconductor laser device on which the modulation frequency signal is not superimposed. FIG. 30B is a graph of a spectrum waveform in the longitudinal mode of the semiconductor laser device according to the fourth embodiment on which the modulation frequency signal is superimposed. The spectrum width in the longitudinal mode shown in FIG. 30B spreads when the waveform changes. Further, as shown in FIG. 26, energy is dispersed in a plurality of longitudinal modes. Therefore, a peak value is lowered in obtaining the same optical output energy (reference FIG. 30A versus FIG. 30B). Consequently, by forming the plurality of longitudinal modes and by superimposing the modulation frequency signal, the threshold value Pth of the stimulated Brillouin scattering can be increased.

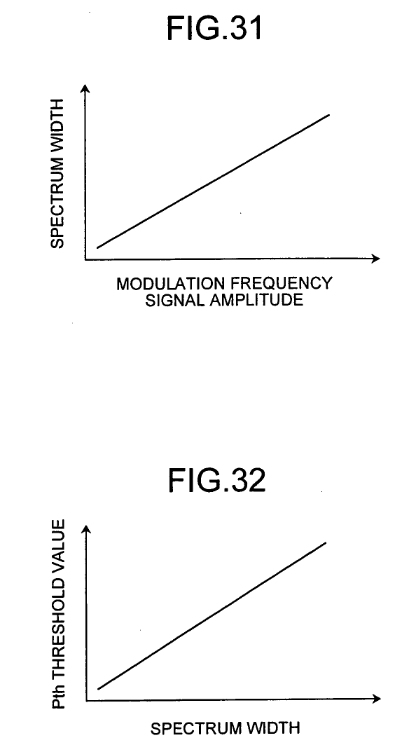

In general, when the amplitude of the modulation frequency signal is increased, the spectrum width of each longitudinal mode increases as shown in FIG. 31. When the spectrum width increases, the threshold value Pth of the stimulated Brillouin scattering increases in the optical output as shown in FIG. 32. Therefore, it is possible to realize a semiconductor laser device of a stable high optical output capable of reducing the stimulated Brillouin scattering.

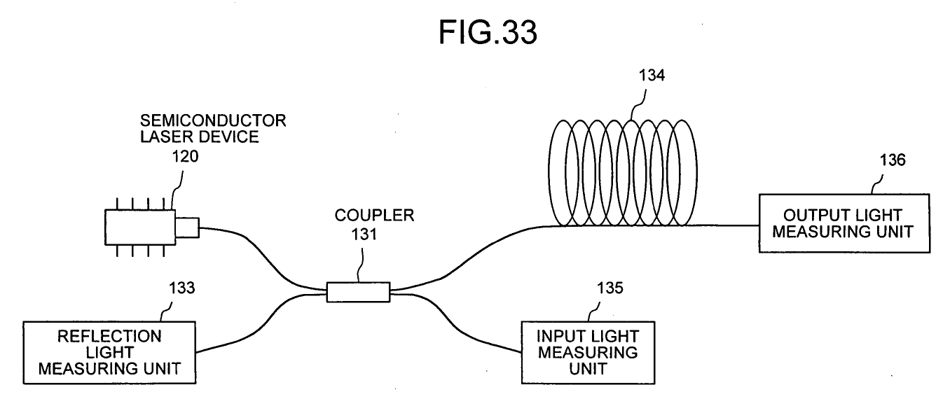

It is explained below that the semiconductor laser device according to the fourth embodiment suppresses the stimulated Brillouin scattering, and can resultantly lower the relative intensity noise. FIG. 33 is a schematic view of a structure of a measuring device that detects an occurrence level of the stimulated Brillouin scattering and measures the relative intensity noise. The semiconductor laser device 120 and a reflection light measuring unit 133 are disposed at one side of this measuring device via a coupler 132. A transmission optical fiber 134 and an input light measuring unit 135 are disposed at the other side of the measuring device via the coupler 132. The semiconductor laser device 120 and the reflection light measuring unit 133 are connected to the transmission optical fiber 134 and the input light measuring unit 135 via the coupler 132. The transmission optical fiber 134 is connected to an output light measuring unit 136. The transmission optical fiber 134 is a TrueWave-RS (R) as a non-zero dispersion shift fiber having a length of 37 kilometers.

In the measuring device shown in FIG. 33, a light having a constant ratio to the intensity of the laser light output from the semiconductor laser device 120 is incident to the input light measuring unit 135. A light having a constant ratio to the intensity of the laser light scattered by the transmission optical fiber 134 and returned is incident to the reflection light measuring unit 133.

When the stimulated Brillouin scattering is generated, the intensity of the light incident to the reflection light measuring unit 133 increases. Therefore, whether the stimulated Brillouin scattering is generated can be decided by calculating a ratio (i.e. a return loss) of the intensity of the light incident from the semiconductor laser device 120 to the transmission optical fiber 134 to the intensity of the light scattered by the transmission optical fiber 134 and returned. In general, when the semiconductor laser device is used as the pump source in the optical communications, it is considered that a background level based on the Rayleigh scattering is obtained when the return loss is suppressed to around −28 decibels to −30 decibels. In this case, it is considered that no stimulated Brillouin scattering is generated, and that there is no problem when the semiconductor laser device is used as the pump source. The Rayleigh scattering level is a value that changes depending on a kind of the transmission optical fiber 134.

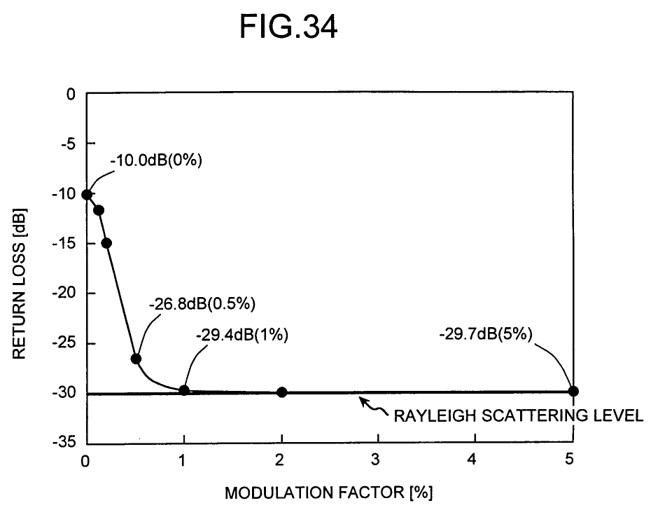

FIG. 34 is a graph of a relation between a modulation factor and a return loss according to the fourth embodiment. In FIG. 34, the Rayleigh scattering level is about −30 decibels. When the modulation factor increases, the return loss decreases, and finally becomes not higher than the Rayleigh scattering level. Consequently, the Rayleigh scattering level becomes dominant. In FIG. 34, the return loss is −10.0 decibels when there is no modulation factor (i.e. 0%). However, when the modulation factor is 0.5%, the return loss is lowered to −26.8 decibels. When the modulation factor is 1%, the return loss becomes substantially equal to the Rayleigh scattering level, and there is no influence of the stimulated Brillouin scattering at all. When the modulation factor is 5%, the return loss becomes −29.7 decibels. In this case, there is no influence of the stimulated Brillouin scattering either.

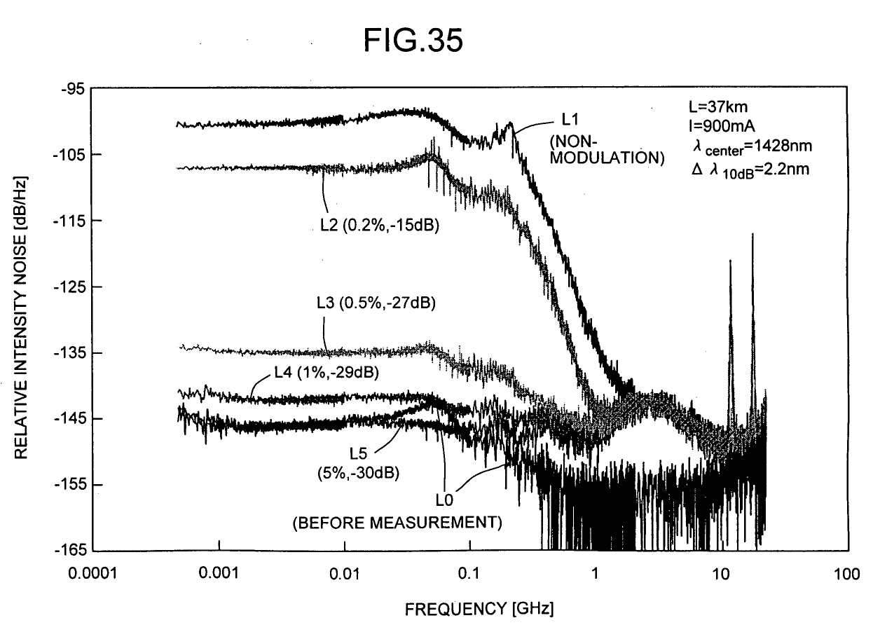

When the relative intensity noise is measured at the output end of the transmission optical fiber 134, that is, when the output light measuring unit 136 measures the relative intensity noise, a result as shown in FIG. 35 is obtained. FIG. 35 is a graph of frequency characteristics of the relative intensity noise when the modulation factor is changed. In this case, a drive current of the semiconductor laser device is 900 milliampere, a wavelength center λ_{center} is 1424 nanometers, a wavelength width Δλ₁₀decibels which is down by 10 decibels from a peak is 2.2 nanometers, and the transmission optical fiber length L is 37 kilometers as explained above. In FIG. 35, when there is no modulation, there is large relative intensity noise in the low-frequency region as shown by the data L1. In other words, the relative intensity noise increases rapidly at 1 gigahertz to 0.1 gigahertz. The relative intensity noise of about −100 decibels continues up to about 0 hertz.

When the modulation factor is increased and when the return loss is decreased, the relative intensity noise in the low-frequency region decreases sequentially. When the modulation factor is 0.2% (i.e. when the return loss is equal to −15 decibels), the relative intensity noise in the low-frequency region slightly decreases to about −105 decibels as shown by the data L2. When the modulation factor is 0.5% (i.e. when the return loss is equal to −27 decibels), the relative intensity noise in the low-frequency region rapidly decreases to about −135 decibels as shown by the data L3. When the modulation factor is 1% (i.e. when the return loss is equal to −29 decibels), the relative intensity noise in the low-frequency region further decreases to about −140 decibels as shown by the data L4. When the modulation factor is 5% (i.e. when the return loss is equal to −30 decibels), the relative intensity noise in the low-frequency region further decreases to about −145 decibels as shown by the data L5. In the low-frequency region, the relative intensity noise becomes substantially equal to that shown by the data L0 before the measurement. The relative intensity noise before the measurement has a projection shape near about 0.1 gigahertz, and the relative intensity noise increases. By carrying out the modulation, relative intensity noise of a low value without the projection shape can be obtained.

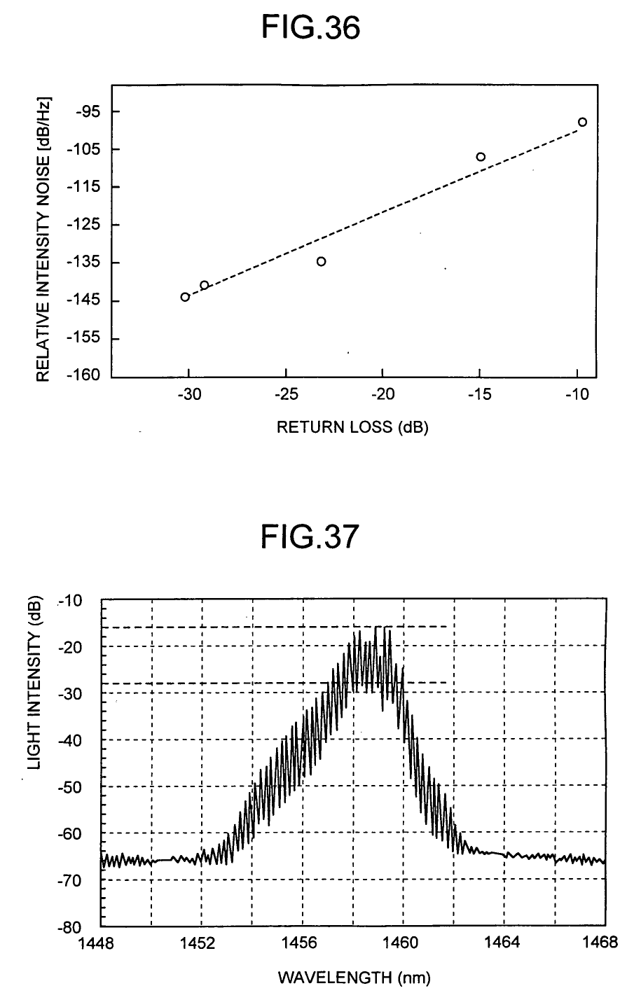

This means that it is capable of lowering the relative intensity noise by reducing the return loss and suppressing the stimulated Brillouin scattering, as shown in FIG. 36. This similarly applies to an embodiment explained later, where the result shown in FIG. 3 can be obtained. In this case, it is preferable that a return loss level which is larger than the Rayleigh scattering level by about +2 decibels is a threshold value at which the stimulated Brillouin scattering is suppressed. It is more preferable that a return loss level which is larger than the Rayleigh scattering level by about +1 decibels is a threshold value at which the stimulated Brillouin scattering is suppressed.

In a fourth embodiment of the present invention, the semiconductor laser device modulates a laser light, thereby to suppress the stimulated Brillouin scattering and lower the relative intensity noise as a result. On the other hand, in the fifth embodiment, the number of modes of the semiconductor laser device is increased, thereby to suppress the stimulated Brillouin scattering and lower the relative intensity noise as a result.

The semiconductor laser device according to the fifth embodiment has the same structure as that of the semiconductor laser device 120 according to the fourth embodiment. However, the modulation signal applying unit 122 does not modulate the laser light. As shown in FIG. 3, according to the fifth embodiment, a plurality of longitudinal modes exist within the selective wavelength characteristics as represented by a FWHM Δλh of the oscillation spectrum 16 of the semiconductor laser device having the grating 113. According to the conventional DBR (distributed Bragg reflector) semiconductor laser device or DFB semiconductor laser device, when the cavity length L is 800 micrometers or larger, it is difficult to carry out the oscillation in the single longitudinal mode. Therefore, a semiconductor laser device having this cavity length L has not been used. However, like in the fourth embodiment, the semiconductor laser device according to the fifth embodiment positively sets the cavity length L to 800 micrometers or larger, thereby to carry out a laser oscillation by including a large number of longitudinal modes within the FWHM Δλh of the oscillation spectrum 16.

In the longitudinal mode selected by the grating 113, how to determine the number of longitudinal modes, each of which has an intensity difference equal to or less than 10 decibels from a maximum intensity, and how to determine the spectrum width Δλ_{RMS} of the oscillation spectrum according to the RMS method will be explained. Basically, the number of longitudinal modes, each of which has an intensity difference equal to or less than 10 decibels from a maximum intensity, and the spectrum width Δλ_{RMS} according to the RMS method are determined based on a structure of the grating 113.

First, there is a structure that changes the grating length Lg or the coupling coefficient k of the grating 113. In general, when the grating length Lg becomes smaller, the FWHM Δλh of the oscillation spectrum becomes larger, and the spectrum width Δλ_{RMS} also becomes larger. The number of longitudinal modes, each of which has an intensity difference equal to or less than 10 decibels from a maximum intensity also increases. In order to select a desired longitudinal mode, it is necessary that a product k·Lg of the coupling coefficient k and the grating length Lg is at least a predetermined value. However, by changing the value of the grating length Lg in this condition, the number of longitudinal modes can be changed, and the spectrum width Δλ_{RMS} can be increased.

It is also effective to change the grating period of the grating 113. FIG. 4 is an illustration of an example chirped grating that periodically changes the grating period of the grating 113. With this arrangement, it is possible to generate a fluctuation in the wavelength selective characteristics of the grating, increase the FWHM Δλh of the oscillation spectrum, and increase the spectrum width Δλ_{RMS} as a result. Then, the number of longitudinal modes, each of which has an intensity difference equal to or less than 10 decibels from a maximum intensity is increased. In other words, as shown in FIG. 5, by increasing the FWHM Δλh to a FWHM wc, it is possible to increase the spectrum width Δλ_{RMS} and increase the number of longitudinal modes.

As shown in FIG. 4, the grating 113 has a structure that has an average period of 220 nanometers, and that repeats a cyclic fluctuation (i.e., a deviation) of +0.02 nanometer in a period of C. Based on the cyclic fluctuation of this ±0.02 nanometer, a reflection band of the grating 113 has a FWHM of about 2 nanometers. With this arrangement, it is possible to change the number of longitudinal modes, each of which has an intensity difference equal to or less than 10 decibels from a maximum intensity.

In the example shown in FIG. 4, while the chirped grating that changes the grating period in the constant cycle C is used, it is also possible to change the grating period at random between a period Λ₁ (220 nanometers +0.02 nanometer) and a period Λ₂ (220 nanometers −0.02 nanometer).

Further, as shown in FIG. 6A, the grating may have a cyclic fluctuation that alternately repeats one period Al and one period Λ₂. Further, as shown in FIG. 6B, the grating may have a cyclic fluctuation that alternately repeats a plurality of periods Λ₃ and a plurality of periods Λ₄. Further, as shown in FIG. 6C, the grating may have a cyclic fluctuation that alternately repeats a continuous plurality of periods Λ₅ and a continuous plurality of periods Λ₆. Further, it is also possible to dispose the grating by complementing periods having dispersed different values of periods Λ₁, Λ₃, and Λ₅, and periods Λ₂, Λ₄, and Λ₆.

As explained above, by adjusting the structure and the like of the grating 113, it is possible to change the number of longitudinal modes, each of which has an intensity difference equal to or less than 10 decibels from a maximum intensity, and change the spectrum width Δλ_{RMS} of the oscillation spectrum formed in the plurality of longitudinal modes, according to the RMS method. FIG. 37 to FIG. 39 are graphs of an oscillation waveform of the semiconductor laser device that changes the number of longitudinal modes and the spectrum width Δλ_{RMS} by adjusting the structure and the like of the grating 113. In FIG. 37, a longitudinal mode having maximum intensity exists near 1457.5 nanometers, and the maximum light intensity is about −16 decibels. There are fourteen longitudinal modes, each of which has an intensity difference equal to or less than 10 decibels from a maximum intensity. In other words, there are fourteen longitudinal modes, each of which has the light intensity of about −26 decibels or more in the graph shown in FIG. 37.

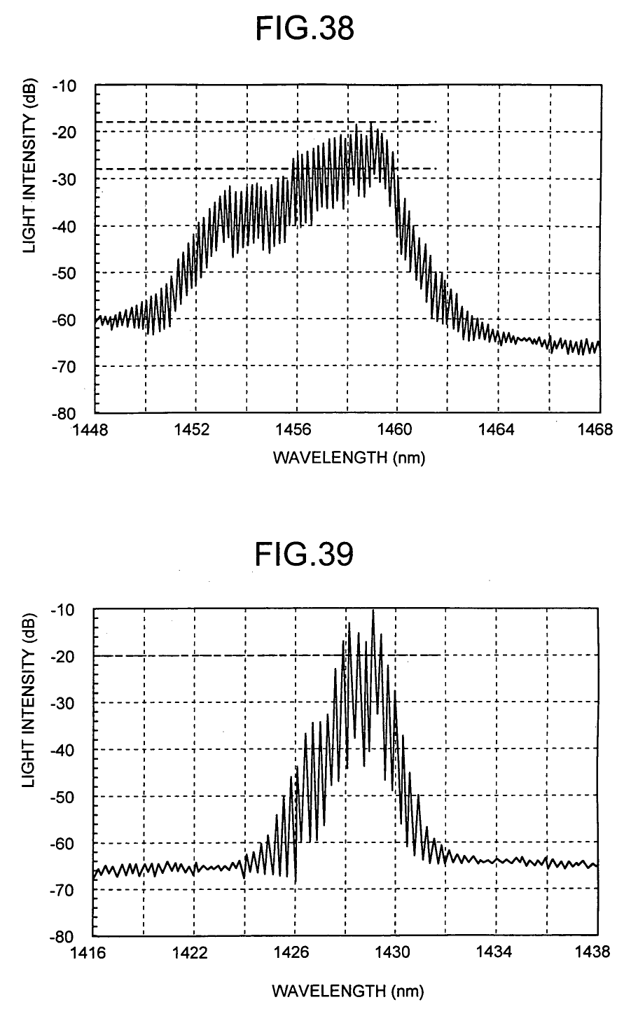

FIG. 38 is a graph of an oscillation waveform of the semiconductor laser device in which the grating 113 has a structure different from that shown in FIG. 37. A longitudinal mode having maximum intensity exists near 1459.5 nanometers, and the maximum light intensity is about −18 decibels. There are twenty longitudinal modes, each of which has an intensity difference equal to or less than 10 decibels from a maximum intensity. In other words, there are twenty longitudinal modes, each of which has the light intensity of about −28 decibels or more in the graph shown in FIG. 38.

FIG. 39 is a graph of an oscillation waveform of a semiconductor laser device having less than ten longitudinal modes, as a comparative example. In FIG. 39, a longitudinal mode having maximum intensity exists near 1429 nanometers, and the maximum light intensity is about −10 decibels. There are six longitudinal modes, each of which has an intensity difference equal to or less than 10 decibels from a maximum intensity. In other words, there are six longitudinal modes, each of which the light intensity of about −20 decibels or more in the graph shown in FIG. 39.

A correlation between the number of longitudinal modes, each of which has an intensity difference equal to or less than 10 decibels from a maximum intensity, the spectrum width of the oscillation spectrum, and the stimulated Brillouin scattering will be checked next. It is shown below that the semiconductor laser device according to the fifth embodiment can suppress the occurrence of the stimulated Brillouin scattering and can reduce the relative intensity noise. Specifically, the measuring device shown in FIG. 33 measures a return loss in a plurality of semiconductor laser devices.

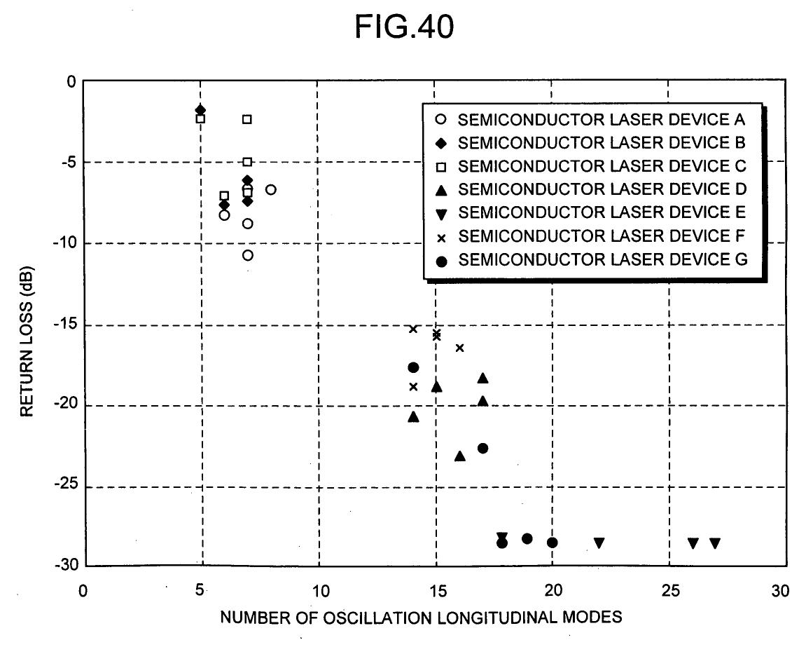

The measuring device measures the return loss in semiconductor laser devices A to G by changing temperatures of these semiconductor laser devices. The measuring device measures the temperatures of the semiconductor laser devices at 5° C., 15° C., 25° C., 35° C., and 45° C. respectively. FIG. 40 is a graph of a relation between the number of longitudinal modes and the return loss when an intensity difference from a maximum intensity is equal to or less than 10 decibels in the measurement. The number of longitudinal modes changes for the same semiconductor laser device because of an influence of a temperature change. While the temperature of the semiconductor laser device influences the number of longitudinal modes, the temperature change does not substantially give a direct influence to the return loss. Specifically, at any temperature, when the number of longitudinal modes is ten or more, each of which has an intensity difference equal to or less than 10 decibels from a maximum intensity, the return loss becomes lower than −13 decibels. When the number of longitudinal modes is eighteen or more, the return loss becomes not higher than −28 decibels.

In FIG. 40, the Rayleigh scattering level is −28 decibels. Therefore, when the number of longitudinal modes is eighteen or more, the stimulated Brillouin scattering can be suppressed, and it becomes possible to lower the relative intensity noise corresponding to the return loss shown in FIG. 35. In this case, like in the fourth embodiment, it is preferable that a return loss level which is larger than the Rayleigh scattering level by about +2 decibels is a threshold value at which the stimulated Brillouin scattering is suppressed. It is more preferable that a return loss level which is larger than the Rayleigh scattering level by about +1 decibels is a threshold value at which the stimulated Brillouin scattering is suppressed.

In a fourth embodiment of the present invention, the semiconductor laser device modulates a laser light, thereby to suppress the stimulated Brillouin scattering and lower the relative intensity noise as a result. In the fifth embodiment, the number of modes of the semiconductor laser device is increased, thereby to suppress the stimulated Brillouin scattering and lower the relative intensity noise as a result. On the other hand, in the sixth embodiment, the laser light output from the semiconductor laser device is attenuated, thereby to suppress the stimulated Brillouin scattering and lower the relative intensity noise as a result.

FIG. 15 is a longitudinal cross-sectional view of a structure of the semiconductor laser module according to the sixth embodiment of the present invention. In FIG. 15, this semiconductor laser module has the semiconductor laser device 31 that corresponds to the semiconductor laser device 120. The semiconductor laser module has the package 39 formed with Cu—W alloy or the like as a casing. The Peltier device 38 is disposed as a temperature controller on the internal bottom surface of the package 39. The base 37 is disposed on the Peltier device 38. The heat sink 37a is disposed on the base 37.

A current (not shown) is given to the Peltier device 38, which is cooled or heated based on the polarity of the current. In order to prevent a deviation in the oscillation wavelength due to a rise in the temperature of the semiconductor laser device 31, the Peltier device 38 mainly functions as a cooler. In other words, when a laser light has a wavelength longer than a desired wavelength, the Peltier device 38 cools the semiconductor laser device to a low temperature. When a laser light has a wavelength shorter than a desired wavelength, the Peltier device 38 heats the semiconductor laser device to a high temperature. A controller (not shown) controls the Peltier device 38 to control the temperature based on a detection value of a thermistor 38a disposed adjacent to the semiconductor laser device 31 on the heat sink 37a. The controller controls the Peltier device 38 to keep the temperature of the heat sink 37a always at a constant level.

When the drive current of the semiconductor laser device 31 increases, the controller (not shown) controls the Peltier device 38 to lower the temperature of the heat sink 37a. By controlling the temperature, it is possible to improve the wavelength stability of the semiconductor laser device 31, which is effective to improve the productivity. It is preferable that the heat sink 37a is formed with a material having high thermal conductivity such as diamond, for example. When the heat sink 37a is formed with diamond, suppressing heating at the time of injecting a high current can be achieved. In this case, the wavelength stability further improves, and the temperature control becomes easy.

The heat sink 37a on which the semiconductor laser device 31 and the thermistor 38a are disposed, the first lens 32, and the monitor photodiode 36 are disposed on the base 37. A laser light emitted from the semiconductor laser device 31 is guided into the optical fiber 35 via the first lens 32, the isolator 33, and the second lens 34, and is guided onto the optical fiber 35. The monitor photodiode 36 monitors and detects a light leaked out from the reflection coating of the semiconductor laser device 31.

The semiconductor laser module according to the sixth embodiment has the following characteristics. The optical center of the second lens 34 is deviated to any one of arrow-mark directions X, Y, and Z from an optical axis of a laser light emitted from the semiconductor laser device 31 via the first lens 32 and the isolator 33. The X direction refers to a height direction (i.e., up and down directions on the drawing) of the semiconductor laser module. The Y direction refers to a width direction (i.e., a perpendicular direction on the drawing) of the semiconductor laser module. The Z direction refers to a longitudinal direction (i.e., left and right directions on the drawing) of the semiconductor laser module. This semiconductor laser module is intentionally defocused. In other words, the optical coupling efficiency of the coupling between the second lens 34 and the optical fiber 35 is made intentionally small. From a viewpoint of the reliability of coupling, it is preferable that the coupling is deviated to the Z direction, as the tolerance in this direction is large.

Through this defocusing, even when a sufficiently large drive current is applied to the semiconductor laser device 31, a laser light having smaller intensity than that of the laser light emitted from the semiconductor laser device 31 propagates though the optical fiber 35 that is optically coupled with the second lens 34.

Therefore, this semiconductor laser module can output a laser light of small intensity in the state that a large drive current is applied to the semiconductor laser device 31. As described above, it is possible to satisfy an optimum condition used for the pump source of the co-propagating pumping system, that is, a condition for obtaining the pump light of small intensity while preventing the aggravation of the relative intensity noise by providing the large drive current.

FIG. 41 is a graph of a relation between an attenuation factor and a return loss based on a defocusing. The measuring device shown in FIG. 33 is used to measure the return loss. The attenuation factor is obtained based on the return loss of −11 decibels when there is no attenuation. As shown in FIG. 41, when the attenuation factor becomes −3 decibels or larger, the return loss becomes not larger than −28 decibels, and the stimulated Brillouin scattering is suppressed. The Rayleigh scattering level is −30 decibels.

In other words, in the sixth embodiment, when the attenuation factor increases based on the defocusing, the return loss decreases, and the stimulated Brillouin scattering can be suppressed, like in the fourth and fifth embodiments. As a result, it is capable of lowering the relative intensity noise corresponding to the return loss as shown in FIG. 35. In this case, like in the fourth and fifth embodiments, it is preferable that a return loss level which is larger than the Rayleigh scattering level by about +2 decibels is a threshold value at which the stimulated Brillouin scattering is suppressed. It is more preferable that a return loss level which is larger than the Rayleigh scattering level by about +1 decibels is a threshold value at which the stimulated Brillouin scattering is suppressed.

It is also possible to intentionally lower the optical coupling efficiency by adjusting the layout of other optical lenses or optical parts than the second lens 34 within the module.

The semiconductor laser module according to a sixth embodiment of the present invention intentionally defocuses to lower the intensity of the laser light. On the other hand, in the seventh embodiment, an optical attenuator is provided at the output end of the semiconductor laser module or adjacent to the output end of the semiconductor laser module via the optical fiber.

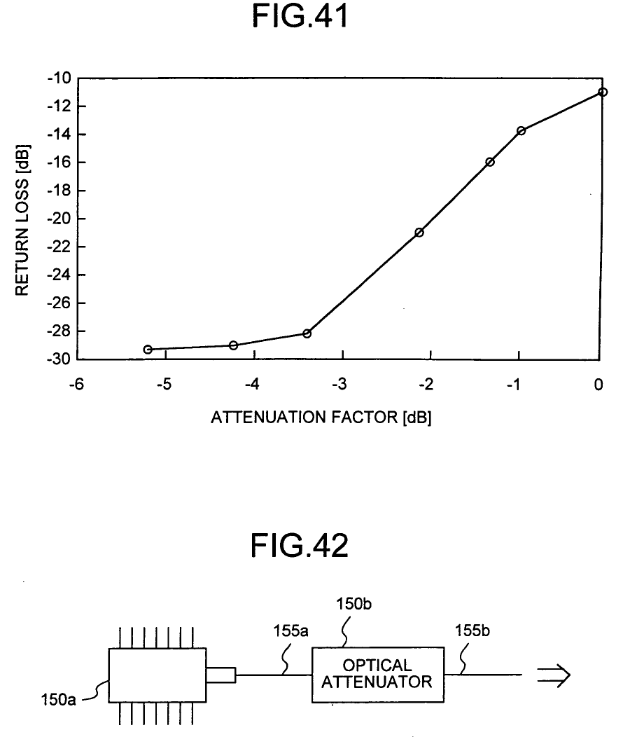

FIG. 42 is a block diagram of a schematic structure of a semiconductor laser module according to the fourth embodiment of the present invention. In FIG. 42, a semiconductor laser module 150a that does not carry out a defocusing has its output end connected to one end of an optical fiber 155a. The other end of the optical fiber 155a is connected to an input end of an optical attenuator. An output end of the optical attenuator 150b is connected to one end of an optical fiber 155b.

In other words, the optical attenuator 150b attenuates the output power of the laser light output from the semiconductor laser module 150a. The attenuated result works as the pump light of the Raman amplifier.

In the seventh embodiment, the increase in the attenuation factor lowers the return loss, suppresses the stimulated Brillouin scattering, and lowers the relative intensity noise corresponding to the return loss as shown in FIG. 35, in a similar manner to that in the third and fourth embodiments. In this case, like in the third and fourth embodiments, it is preferable that a return loss level which is larger than the Rayleigh scattering level by about +2 decibels is a threshold value at which the stimulated Brillouin scattering is suppressed. It is more preferable that a return loss level which is larger than the Rayleigh scattering level by about +1 decibel is a threshold value at which the stimulated Brillouin scattering is suppressed.

In the seventh embodiment, as the optical attenuator drops the final output without changing the coupling state of the laser from the conventional state, it is possible to obtain effects similar to those in the sixth embodiment. At the same time, a module portion that oscillates the laser light can be shared.

In an eighth embodiment of the present invention, the semiconductor laser module of the semiconductor laser device explained in any one of the fourth and fifth embodiments, or the semiconductor laser module explained in any one of the sixth and seventh embodiments is applied to the Raman amplifier.

FIG. 18 is a block diagram of a structure of the Raman amplifier employing the co-propagating pumping system. In FIG. 18, the WDM coupler 45′ is provided adjacent to the isolator 43. The WDM coupler 45′ is connected with the circuit having the semiconductor laser modules 40a′ to 60d′, the polarization combining couplers 41a′ and 61b′, and the WDM coupler 42′ that correspond to the semiconductor laser module of the semiconductor laser device according to any one of the fourth and fifth embodiments, or the semiconductor laser module according to any one of the sixth and seventh embodiments. The WDM coupler 45′ carries out the co-propagating pumping of outputting the pump light output from the WDM coupler 42′ to the same direction as that for the signal light. In this case, the semiconductor laser modules 40a′ to 60d′ use semiconductor laser modules corresponding to the semiconductor laser module of the semiconductor laser device according to any one of the fourth and fifth embodiments, or the semiconductor laser module according to any one of the sixth and seventh embodiments. Therefore, the co-propagating pumping in the lowered state of the relative intensity noise can be effectively carried out.

FIG. 20 is a block diagram of a structure of the Raman amplifier employing the bidirectional pumping system. In FIG. 20, portions common to those in FIG. 18 are attached with identical reference numerals, and their explanation will be omitted. The Raman amplifier shown in FIG. 20 additionally has the WDM coupler 42, the semiconductor laser modules 40a to 60d, and the polarization combining couplers 41a and 41b, in the structure of the Raman amplifier shown in FIG. 18. Based on this structure, the Raman amplifier carries out both the counter-propagating pumping and the co-propagating pumping. For the semiconductor laser modules 40a to 60d that carry out the counter-propagating pumping, it is not particularly necessary to use the semiconductor laser device or the semiconductor laser module explained in the fourth to seventh embodiments.

Each of the semiconductor laser modules 40a and 40b outputs a laser light having a plurality of longitudinal modes to the polarization combining coupler 41a via the polarization maintaining fiber 51. Each of the semiconductor laser modules 40c and 40d outputs a laser light having a plurality of longitudinal modes to the polarization combining coupler 41b via the polarization maintaining fiber 51. The laser lights that the semiconductor laser modules 40a and 40b oscillate have the same wavelengths. The laser lights that the semiconductor laser modules 40c and 40d oscillate have the same wavelengths, which are different from the wavelengths of the laser lights that the semiconductor laser modules 40a and 40b oscillate. This is because the Raman amplification has polarization dependency. The polarization combining couplers 41a and 41b output laser lights after solving the polarization dependency.

The WDM coupler 42 combines the laser lights having different wavelengths that are output from the polarization combining couplers 41a and 41b. The WDM coupler 42 outputs a combined result of the laser lights to the amplification fiber 44 as a pump light for Raman amplification, via the WDM coupler 45. A signal light to be amplified is input to the amplification fiber 44 to which the pump light is input. The amplification fiber 44 Raman amplifies this signal light.

In the bidirectional pumping system, the semiconductor laser modules 40a′ to 60d′ use the semiconductor laser device explained in the fourth embodiment. As a result, the co-propagating pumping in the lowered state of the relative intensity noise can be effectively carried out.

As explained above, the Raman amplifier shown in FIG. 18 or FIG. 20 can be applied to the WDM communication system. FIG. 22 is a block diagram of a schematic structure of the WDM communication system to which the Raman amplifier shown in any one of FIG. 18 or FIG. 20 is applied.

In FIG. 22, the optical multiplexer 60,multiplexes optical signals having wavelengths λ1 to λn that are transmitted from the plurality of transmitters Tx1 to Txn, and integrates the multiplexed signals into the one optical fiber 65. The plurality of Raman amplifiers 61 and 63 corresponding to the Raman amplifiers shown in FIG. 18 or FIG. 20 are disposed with a distance between them on a transmission line of the optical fiber 65, and amplify attenuated optical signals. The optical demultiplexer 64 demultiplexes the signal transmitted through the optical fiber 65 into optical signals having the wavelengths λ1 to λn. The receivers R×1 to R×n receive these optical signals. In some cases, an add/drop multiplexer (ADM) that adds or drops an optical signal of an optional wavelength is inserted into the optical fiber 65.

In the eighth embodiment, the semiconductor laser device explained in any one of the fourth and fifth embodiments or the semiconductor laser module explained in any one of the sixth and seventh embodiments is used as the pump source for Raman amplification. It is apparent that the application is not limited to this, and it is also possible to use the semiconductor laser device or the semiconductor laser module as an EDFA pump source of 980 nanometers or 1480 nanometers.

It is explained in the above embodiments that the semiconductor laser device has the grating 113 in a part of the region adjacent to the active layer or the grating having fluctuation in the whole region adjacent to the active layer. The semiconductor laser device outputs a laser light having a plurality of longitudinal modes. The semiconductor laser device according to the present invention is not limited to this structure, and a semiconductor laser device of a multimode laser is sufficient. For example, the semiconductor laser device may be a Fabry-Perot cavity. Except in the fifth embodiment, the semiconductor laser device can be applied to a single-mode laser such as the DFB laser.

As explained above, according to the embodiments of the present invention, there is an effect that, by limiting the number of the longitudinal modes to not larger than 60, each of which has an intensity difference equal to or less than 10 decibels from a maximum intensity, the semiconductor laser device can decrease the intensity of relative intensity noise after a transmission over a predetermined distance.

When an optical amplifier is structured by using the semiconductor laser device as a pump source for pump light, the optical amplifier can suppress the fluctuation in the pump light. Therefore, there is an effect that the optical fiber amplifier having stable amplification gain can be realized.

Further, the embodiments of the present invention have the effect that the relative intensity noise after the transmission can be lowered, by the following arrangement. The modulation unit modulates the laser light to maintain the modulation factor 1%, thereby to give a return loss of a stimulated Brillouin scattering having a value not larger than the Rayleigh scattering level that is added with 2 decibels. Alternatively, the number of high-output longitudinal modes is set to eighteen or more by the grating, thereby to give a return loss of a stimulated Brillouin scattering having a value not larger than the Rayleigh scattering level that is added with 2 decibels. Alternatively, the optical coupling lens system optically couples the semiconductor laser device with the optical fiber in a state that the optical coupling efficiency is deviated from a maximum efficient position, thereby to give a return loss of a stimulated Brillouin scattering having a value not larger than the Rayleigh scattering level that is added with 2 decibels. Alternatively, the optical attenuator carries out the attenuation, thereby to give a return loss of a stimulated Brillouin scattering having a value not larger than the Rayleigh scattering level that is added with 2 decibels.

The characteristic embodiments of the present invention are explained above to make a complete and clear disclosure of the present invention. However, the attended claims are not limited to the above embodiments. The present invention includes all other modifications and replaceable structures that those skilled in the art can create within the basic scope described in the present specification.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor laser device, which is used as a pump source for an optical fiber amplifier that amplifies a light based on a Raman amplification employing a co-propagating pumping system, comprising:
an emission facet with a first reflection coating;
a reflection facet with a second reflection coating;
an active layer that is formed between the first reflection coating and the second reflection coating; and
an optical cavity that is formed by the emission facet and the reflection facet, and emits a light of which number of longitudinal modes is equal to or more than 2 and equal to or less than 60, wherein each longitudinal mode has an intensity difference equal to or less than 10 decibels from a maximum intensity.

2. The semiconductor laser device according to claim 1, wherein a length of the optical cavity is equal to or longer than 800 micrometers.

3. A semiconductor laser device comprising:
an emission facet with a first reflection coating;
a reflection facet with a second reflection coating;
an active layer that is formed between the first reflection coating and the second reflection coating; and
a grating that is disposed adjacent to the active layer and that selects a light of which number of longitudinal modes is equal to or more than 2 and equal to or less than 60, wherein each longitudinal mode has an intensity difference equal to or less than 10 decibels from a maximum intensity.

4. The semiconductor laser device according to claim 3, wherein the grating selects a light of a wavelength between 1100 nanometers and 1550 nanometers.

5. The semiconductor laser device according to claim 3, wherein the grating is such that a product of a coupling coefficient and a length of the grating is equal to or less than 0.3.

6. The semiconductor laser device according to claim 3, wherein the grating has either of a randomly changed period and a fixed period.

7. A semiconductor laser module, comprising:
a semiconductor laser device that has
an emission facet with a first reflection coating;
a reflection facet with a second reflection coating;
an active layer that is formed between the first reflection coating and the second reflection coating; and
a grating that is disposed adjacent to the active layer and that selects a light of which number of longitudinal modes is equal to or more than 2 and equal to or less than 60, wherein each longitudinal mode has an intensity difference equal to or less than 10 decibels from a maximum intensity;
an optical fiber that guides a laser light output from the semiconductor laser device to the outside; and
an optical coupling lens system that optically couples the semiconductor laser device and the optical fiber.

8. The semiconductor laser module according to claim 7, further comprising a temperature controller that controls a temperature of the semiconductor laser device.

9. The semiconductor laser module according to claim 7, further comprising an isolator that is disposed within the optical coupling lens system, and that blocks light reflecting from the optical fiber.

10. The semiconductor laser device according to claim 7, wherein the optical fiber has a facet that is coupled with the semiconductor laser device, wherein the facet is tilted so that the light from the semiconductor laser device is incident on the facet of the optical fiber at an oblique angle.

11. An optical fiber amplifier, comprising:
a pump source with a semiconductor laser module including a semiconductor laser device, an optical fiber that guides a laser light output from the semiconductor laser device to the outside, and an optical coupling lens system that optically couples the semiconductor laser device and the optical fiber, wherein the semiconductor laser device includes
an emission facet with a first reflection coating;
a reflection facet with a second reflection coating;
an active layer that is formed between the first reflection coating and the second reflection coating; and
a grating that is disposed adjacent to the active layer and that selects a light of which number of longitudinal modes is equal to or more than 2 and equal to or less than 60, wherein each longitudinal mode has an intensity difference equal to or less than 10 decibels from a maximum intensity;
an optical transmission line to transmit a signal light;
an optical fiber for amplification that is connected to the optical transmission line and amplifies the signal light based on a Raman amplification;
a coupler that inputs a pump light from the pump source into the optical fiber; and
an optical transmission line for the pump light that connects the pump source and the coupler.

12. A semiconductor laser device comprising:
an emission facet with a first reflection coating;
a reflection facet with a second reflection coating;
an active layer formed between the first reflection coating and the second reflection coating, and outputs a laser light having a plurality of longitudinal modes; and
a modulation unit that generates a modulation signal for modulating a bias current injected into the active layer and, superimposes the modulation signal on the bias current, wherein the modulation unit gives a return loss of a stimulated Brillouin scattering equal to or less than a value obtained by adding a predetermined value to a Rayleigh scattering level based on the modulation of the laser light.

13. The semiconductor laser device according to claim 12, wherein the predetermined value is 2 decibels.

14. The semiconductor laser device according to claim 12, wherein the predetermined value is 1 decibel.

15. The semiconductor laser device according to claim 11, further comprising a grating adjacent to the active layer, wherein a plurality of longitudinal modes are generated within a full width at half maximum of an oscillation spectrum based on a setting of a combination of oscillation parameters including a cavity length and wavelength selective characteristics of the grating.

16. A semiconductor laser device comprising:
an emission facet with a first reflection coating;
a reflection facet with a second reflection coating;
an active layer formed between the first reflection coating and the second reflection coating, and outputs a laser light having a plurality of longitudinal modes; and
a grating that selects a plurality of high power longitudinal modes, wherein each longitudinal mode has an intensity difference equal to or less than 10 decibels from a maximum intensity, wherein the grating gives a return loss of a stimulated Brillouin scattering equal to or less than a value obtained by adding a predetermined value to a Rayleigh scattering level based on the selected number of the high power longitudinal modes.

17. The semiconductor laser device according to claim 16, wherein the predetermined value is 2 decibels.

18. The semiconductor laser device according to claim 16, wherein the predetermined value is 1 decibel.

19. A semiconductor laser module, comprising:
a semiconductor laser device that has
an emission facet with a first reflection coating;
a reflection facet with a second reflection coating; and
an active layer formed between the first reflection coating and the second reflection coating, and outputs a laser light having a plurality of longitudinal modes;
an optical fiber that guides a laser light output from the semiconductor laser device to the outside; and
an optical coupling lens system that optically couples the semiconductor laser device and the optical fiber in such a manner that the optical coupling efficiency between the semiconductor laser device and the optical fiber is deviated from a maximum value, wherein
the semiconductor laser module gives a return loss of a stimulated Brillouin scattering equal to or less than a value obtained by adding a predetermined value to a Rayleigh scattering level based on an attenuation of the optical coupling efficiency.

20. A semiconductor laser module, comprising:
a semiconductor laser device that has
an emission facet with a first reflection coating;
a reflection facet with a second reflection coating; and
an active layer formed between the first reflection coating and the second reflection coating, and outputs a laser light having a plurality of longitudinal modes;
an optical fiber that guides a laser light output from the semiconductor laser device to the outside; and
an optical attenuator that attenuates the laser light, wherein
the semiconductor laser module gives a return loss of a stimulated Brillouin scattering equal to or less than a value obtained by adding a predetermined value to a Rayleigh scattering level based on the attenuation by the optical attenuator.

21. The semiconductor laser module according to claim 20, wherein the predetermined value is 2 decibel.

22. The semiconductor laser module according to claim 20, wherein the predetermined value is 1 decibel.

23. The semiconductor laser module according to claim 20, wherein the semiconductor laser device includes a grating that is provided adjacent to the active layer, wherein a plurality of longitudinal modes are generated within a full width at half maximum of an oscillation spectrum based on a setting of a combination of oscillation parameters including a cavity length and wavelength selective characteristics of the grating.

24. A Raman amplifier that uses either of a semiconductor laser device and a semiconductor laser module, as a pump source for a wideband Raman amplification, wherein
the semiconductor laser device has an emission facet with a first reflection coating, a reflection facet with a second reflection coating, an active layer formed between the first reflection coating and the second reflection coating, a modulation unit that generates a modulation signal for modulating a bias current injected into the active layer, and superimposes the modulation signal on the bias current, wherein the modulation unit gives a return loss of a stimulated Brillouin scattering equal to or less than a value obtained by adding a predetermined value to a Rayleigh scattering level based on the modulation of the laser light, and a grating that selects a plurality of high power longitudinal modes, wherein each longitudinal mode has an intensity difference equal to or less than 10 decibels from a maximum intensity, wherein the grating gives a return loss of a stimulated Brillouin scattering equal to or less than a value obtained by adding a predetermined value to a Rayleigh scattering level based on the selected number of the high power longitudinal modes, wherein the semiconductor laser device outputs a laser light having a plurality of longitudinal modes, and
the semiconductor laser module includes a semiconductor laser device that has an emission facet with a first reflection coating, a reflection facet with a second reflection coating, and an active layer formed between the first reflection coating and the second reflection coating, and outputs a laser light having a plurality of longitudinal modes, an optical fiber that guides a laser light output from the semiconductor laser device to the outside; an optical coupling lens system that optically couples the semiconductor laser device and the optical fiber in such a manner that the optical coupling efficiency between the semiconductor laser device and the optical fiber is deviated from a maximum value, wherein the semiconductor laser module gives a return loss of a stimulated Brillouin scattering equal to or less than a value obtained by adding a predetermined value to a Rayleigh scattering level based on an attenuation of the optical coupling efficiency, an optical fiber that guides a laser light output from the semiconductor laser device to the outside, and an optical attenuator that attenuates the laser light, wherein the semiconductor laser module gives a return loss of a stimulated Brillouin scattering equal to or less than a value obtained by adding 2 decibels to a Rayleigh scattering level based on the attenuation by the optical attenuator.
